(19) United States
(12) Patent Application Publication
(10) Pub. No.: US 2025/0008786 A1
(43) Pub. Date: Jan. 2, 2025

(54) DISPLAY PANEL AND ELECTRONIC DEVICE

(71) Applicant: Samsung Display Co., Ltd., Yongin-Si (KR)

(72) Inventors: Donghyun Son, Yongin-si (KR); Sola Lee, Yongin-si (KR); Jongseok Kim, Yongin-si (KR); Seongjun Lee, Yongin-si (KR)

(21) Appl. No.: 18/749,009

(22) Filed: Jun. 20, 2024

(30) Foreign Application Priority Data
Jun. 28, 2023 (KR) 10-2023-0083772

(51) Int. Cl. H10K 59/126; H10K 59/124; H10K 59/65; H10K 59/80

(52) U.S. Cl. CPC H10K 59/126; H10K 59/124; H10K 59/65; H10K 59/879

(57) ABSTRACT

A display panel includes a substrate including a transmissive area, a transistor over the substrate and adjacent to the transmissive area, a light-emitting diode electrically connected to the transistor, a bottom metal layer disposed between the substrate and the transistor and overlapping the transistor, and a plurality of inorganic insulation layers between the bottom metal layer and the light-emitting diode. An opening penetrating at least one of the inorganic insulation layers overlaps the bottom metal layer and thereby, an electronic device with improved image quality of the display panel may be implemented by preventing light emitted from components from entering thin-film transistors.

### CROSS-REFERENCE TO RELATED APPLICATION

This application is based on and claims priority under 35 U.S.C. § 119 to Korean Patent Application No. 10-2023-0083772, filed on Jun. 28, 2023, in the Korean Intellectual Property Office, the disclosure of which is incorporated by reference herein in its entirety.

### BACKGROUND

### 1. Field

One or more embodiments relate to a display panel and an electronic device, and more particularly to a display panel and an electronic device including the display panel and a component disposed below the display panel.

### 2. Description of the Related Art

In general, a display panel such as an organic light-emitting display panel has thin-film transistors arranged in a display area to control the brightness of light-emitting diodes. The thin-film transistors operate so that light of a certain color or colors is emitted from the corresponding light-emitting diodes in response to a transmitted data signal, a drive voltage, and a common voltage.

An electronic device may be a display device including a display panel. The electronic device may further include components disposed below the display panel. The components may include sensors, cameras, etc., which may also emit and detect light, such as visible light and/or infrared light.

### SUMMARY

One component disposed below a display panel may be a light sensor such as an infrared light sensor. The infrared light sensor may include a transmitter that emits infrared light and a receiver that detects the infrared light. When the infrared light emitted by the transmitter is incident on a thin-film transistor of the display panel, the performance of the thin-film transistor may be degraded, which may cause a deterioration of the image quality of the display panel.

The disclosure aims to address several problems including the problems mentioned above. To this end, the disclosure aims to provide a display panel and an electronic device including such a display panel, in which diffracted light is blocked from being incident on a thin-film transistor by removing a portion of an inorganic insulation layer from a component area. However, these tasks are just examples and do not limit the scope of the disclosure.

Additional aspects will be set forth in part in the description which follows and, in part, will be apparent from the description, or may be learned by practice of the presented embodiments of the disclosure.

According to one or more embodiments, a display panel may be provided including, a substrate including a transmissive area, a transistor disposed over the substrate adjacent to the transmissive area, a light-emitting diode electrically connected to the transistor, a bottom metal layer disposed between the substrate and the transistor, overlapping the transistor, and a plurality of inorganic insulation layers disposed between the bottom metal layer and the light-emitting diode, wherein an opening penetrating at least one of the plurality of inorganic insulation layers overlaps the bottom metal layer.

According to one or more embodiments, the display panel may further include an organic insulation layer that at least partially fills the opening in the plurality of inorganic insulation layers.

According to one or more embodiments, the display panel may further include a shielding layer, including a metallic material, at least partially filling the opening of the plurality of inorganic insulation layers.

According to one or more embodiments, the shielding layer may be in contact with the bottom metal layer.

According to one or more embodiments, the opening may have a closed-loop shape when viewed in a plan view.

According to one or more embodiments, the bottom metal layer may include an opening corresponding to the transmissive area, and the opening in the plurality of inorganic insulation layers may overlap with the opening in the bottom metal layer.

According to one or more embodiments, the plurality of inorganic insulation layers may include a plurality of layers with different refractive indices.

According to one or more embodiments, the bottom metal layer may include an opening corresponding to the transmissive area, the opening in the plurality of inorganic insulation layers includes a first inner surface adjacent to the transistor, and a horizontal distance from an edge of the bottom metal layer defining the opening in the bottom metal layer to the first inner surface may be greater than the depth of the opening in the plurality of inorganic insulation layers.

According to one or more embodiments, the opening of the plurality of inorganic insulation layers may further include a second inner surface opposite the first inner surface and adjacent to the transmissive area, and the horizontal distance from the edge of the bottom metal layer to the second inner surface may be greater than the depth of the opening of the plurality of inorganic insulation layers.

According to one or more embodiments, an electronic device may be provided including, a display panel including a display area, a component disposed on a rear surface of the display panel and overlapping the display area, wherein the display panel includes, a substrate including a transmissive area overlapping the component, a transistor disposed over the substrate adjacent to the transmissive area, and a light-emitting diode electrically connected to the transistor, a bottom metal layer arranged between the substrate and the transistor, overlapping the transistor, and a plurality of inorganic insulation layers arranged between the bottom metal layer and the light-emitting diode, wherein an opening penetrating at least one of the plurality of inorganic insulation layers overlaps the bottom metal layer.

According to one or more embodiments, the component may include a sensor or camera.

According to one or more embodiments, the electronic device may further include an organic insulation layer that at least partially fills the openings in the plurality of inorganic insulation layers.

According to one or more embodiments, the electronic device may further include a shielding layer, including a metallic material, at least partially filling the openings of the plurality of inorganic insulation layers.

According to one or more embodiments, the shielding layer may be in contact with the bottom metal layer.

According to one or more embodiments, the opening may have a closed-loop shape when viewed in a plan view.

According to one or more embodiments, the bottom metal layer may include an opening corresponding to the transmissive area, and the opening in the plurality of inorganic insulation layers may overlap with the opening in the bottom metal layer.

According to one or more embodiments, the plurality of inorganic insulation layers may include a plurality of layers with different refractive indices.

According to one or more embodiments, the bottom metal layer may include an opening corresponding to the transmissive area, the opening in the plurality of inorganic insulation layers includes a first inner surface adjacent to the transistor, and a horizontal distance from an edge of the bottom metal layer defining the opening in the bottom metal layer to the first inner surface may be greater than the depth of the opening in the plurality of inorganic insulation layers.

According to one or more embodiments, the opening of the plurality of inorganic insulation layers may further include a second inner surface opposite the first inner surface and adjacent to the transmissive area, and the horizontal distance from the edge of the bottom metal layer to the second inner surface may be greater than the depth of the opening of the plurality of inorganic insulation layers.

According to one or more embodiments, the opening may reduce the amount of light reaching the transistor out of the light emitted from the component.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a perspective view illustrating an electronic device including a display panel according to an embodiment.

FIG. 2 is a cross-sectional view illustrating a portion of an electronic device including a display panel according to an embodiment.

FIG. 3 is an enlarged cross-sectional view illustrating a portion of a display panel according to an embodiment.

FIG. 4 is an equivalent circuit schematic schematically illustrating a pixel of the display panel.

FIG. 5 is an enlarged plan view illustrating a portion of a display panel according to an embodiment.

FIG. 6A is a cross-sectional view schematically illustrating a portion of an electronic device including a display panel according to an embodiment.

FIG. 6B is an enlarged cross-sectional view schematically illustrating a portion of an electronic device including a display panel according to an embodiment.

FIG. 7A is a cross-sectional view schematically illustrating a portion of an electronic device including a display panel according to an embodiment.

FIG. 7B is an enlarged cross-sectional view schematically illustrating a portion of an electronic device including a display panel according to an embodiment.

FIG. 8 is an enlarged plan view illustrating a portion of a display panel according to an embodiment.

FIG. 9A is a cross-sectional view schematically illustrating a portion of an electronic device including a display panel according to an embodiment.

FIG. 9B is an enlarged cross-sectional view schematically illustrating a portion of an electronic device including a display panel according to an embodiment.

FIG. 10A is a cross-sectional view schematically illustrating of a portion of an electronic device including a display panel according to an embodiment.

FIG. 10B is an enlarged cross-sectional view schematically illustrating a portion of an electronic device including a display panel according to an embodiment.

FIG. 11A is a cross-sectional view schematically illustrating a portion of an electronic device including a display panel according to an embodiment.

FIG. 11B is an enlarged cross-sectional view schematically illustrating a portion of an electronic device including a display panel according to an embodiment.

FIG. 12 is an enlarged plan view illustrating a portion of a display panel according to an embodiment.

FIG. 13A is a cross-sectional view schematically illustrating a portion of an electronic device including a display panel according to an embodiment.

FIG. 13B is an enlarged cross-sectional view schematically illustrating a portion of an electronic device including a display panel according to an embodiment.

FIG. 14A is a cross-sectional view schematically illustrating a portion of an electronic device including a display panel according to an embodiment.

FIG. 14B is an enlarged cross-sectional view schematically illustrating a portion of an electronic device including a display panel according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure is subject to various modifications and may have many embodiments, some of which are illustrated in the drawings and further described in the detailed description. The effects and features of the disclosure, and methods of achieving them will become clear with reference to the embodiments described below in detail together with the drawings. However, the disclosure is not limited to the embodiments described herein and may be implemented in various forms.

Hereinafter, embodiments will be described in detail with reference to the accompanying drawings, and when describing with reference to the drawings, the same or corresponding components are given the same reference numerals, and duplicate descriptions thereof will be omitted.

In the following embodiments, the terms first, second, etc. are not intended to be limiting but instead are used to distinguish one component from another.

In the following embodiments, the singular expression includes the plural unless the context clearly indicates otherwise.

In the following embodiments, the terms including or that has, etc. are intended to imply the presence of the recited features or components and do not preclude the possibility of the addition of one or more other features or components.

In the following embodiments, when a portion of a film, area, component, etc. is referred to as being over or on top of another portion, this includes not only when it is directly on top of another portion but also when there are other films, areas, components, etc. arranged therebetween.

In the drawings, components may be exaggerated or reduced in size for ease of illustration. For example, the size and thickness of each configuration shown in the drawings may be arbitrary for ease of description and the disclosure is not necessarily limited to the relative proportions shown in the drawings.

In some embodiments, a particular sequence of processes may be performed in an order different from that described. For example, two processes described in succession may be performed substantially simultaneously or may be performed in the opposite order from the order described.

In the following embodiments, references to films, areas, components, etc. being connected include direct connections between films, areas, components, and/or indirect connections between films, areas, and components, with other films, areas, and components, arranged between them. For example, when referring to films, areas, components, etc. as being electrically connected herein, it refers to films, areas, components, etc. being directly electrically connected and/or indirectly electrically connected with other films, areas, components, etc. arranged therebetween.

The terms x-axis, y-axis, and z-axis are not limited to, but may be interpreted in a broad sense to include, three axes in a Cartesian coordinate system. For example, the x-axis, y-axis, and z-axis may be orthogonal to each other but may instead be different directions that are not orthogonal to each other.

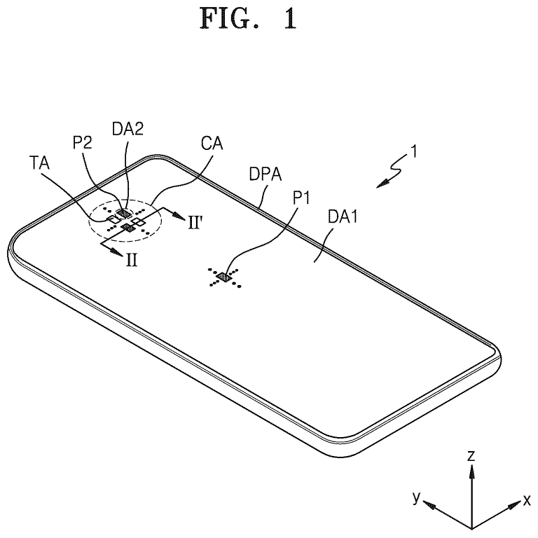

FIG. 1 is a perspective view illustrating an electronic device 1 including a display panel, according to an embodiment.

Referring to FIG. 1, in some embodiments, the electronic device 1 is a device capable of displaying an image and may be a portable electronic device such as a mobile phone, smart phone, tablet personal computer, mobile communication terminal, electronic notebook, e-book, portable multimedia player (PMP), navigation, ultra mobile personal computer (UMPC), etc. Alternatively, the electronic device 1 may be applied to various other applications or products such as televisions, laptops, monitors, billboards, internet of things (IOT), etc. In addition, the electronic device 1 according to an embodiment may be applied to a wearable device, such as a smart watch, a watch phone, an eyewear display, and a head mounted display (HMD). In addition, the electronic device 1 according to an embodiment may be applied to an instrument panel of an automobile or other vehicle, and to a center information display (CID) arranged on the center fascia or dashboard of a vehicle, to a room mirror display in place of a side mirror of a vehicle, to an entertainment screen for the back seat of a vehicle, or to a display screen arranged on the back of a front seat.

The electronic device 1 may include a component area CA, a first display area DA1, and a peripheral area DPA. FIG. 1 shows an example where the first display area DA1 has an approximate quadrilateral shape with rounded corners when viewed from a direction approximately perpendicular to the upper surface of the electronic device 1 (for example, the +z direction). The first display area DA1 may surround at least a portion of the component area CA. Each of the component area CA and the first display area DA1 may display an image separately or together. The peripheral area DPA may be a type of non-display area not containing display elements. The first display area DA1 may be entirely surrounded by the peripheral area DPA.

FIG. 1 illustrates one component area CA located within the first display area DA1. In another embodiment, the electronic device 1 may have two or more component areas CA, and the component areas CA may have different shapes and sizes. When viewed from a direction approximately perpendicular to the upper surface of the electronic device 1 (for example, in the +z direction), the component areas CA may have various shapes, such as a circular shape, an oval shape, a polygonal shape such as a quadrilateral shape, etc., or a star shape, or a diamond shape, etc. In FIG. 1, the component area CA is illustrated as being arranged in the upper center (i.e., in the +y direction from the center) of the first display area DA1, but the component area CA may be more to one side of the first display area DA1, for example, toward the right upper side or the left upper side.

The electronic device 1 may provide an image by utilizing a plurality of first sub-pixels P1 arranged in the first display area DA1 and a plurality of second sub-pixels P2 arranged in the component area CA.

The component area CA may include a second display area DA2 and a transmissive area TA.

The plurality of second sub-pixels P2 may be arranged in the second display area DA2. The plurality of second sub-pixels P2 may emit light to provide a certain image. The image displayed in the component area CA is a second image and may have a lower resolution than the image displayed in the first display area DA1. The transmissive area TA may transmit light, and/or sound. The transmissive area TA may be an area where the second sub-pixel P2 is not arranged. Thus, the number of second sub-pixels P2 per unit area in the component area CA may be smaller than the number of first sub-pixels P1 per unit area in the first display area DA1.

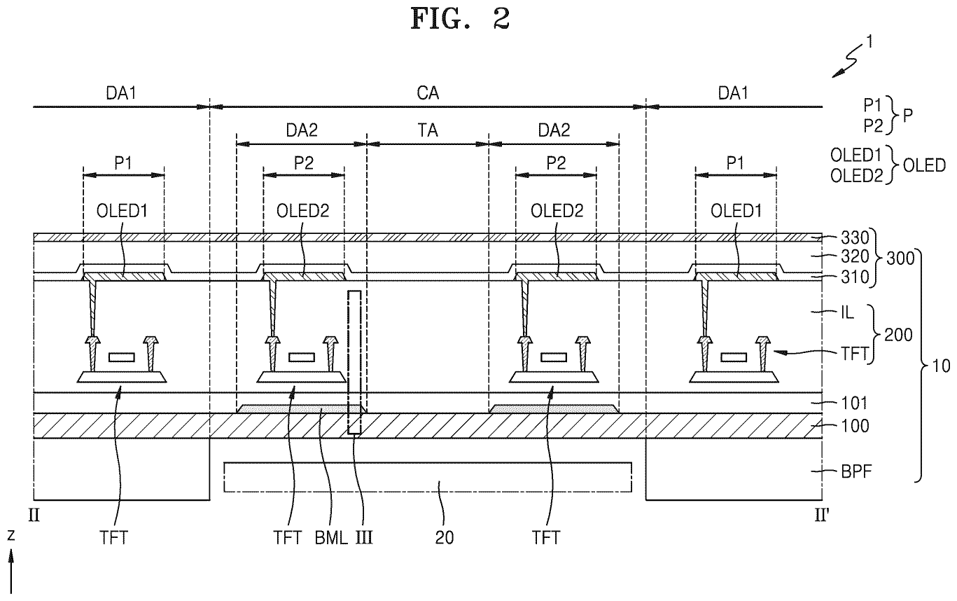

FIG. 2 is a cross-sectional view illustrating a portion of an electronic device including a display panel according to an embodiment.

FIG. 2 shows an example of the display device 1 including a component 20,

which may be an electronic element, disposed below a substrate 100 in the component area CA of the display device 1. The component 20 may be a camera utilizing infrared light or visible light, etc. and may be provided with an imaging element. Alternatively, the component 20 may be a solar cell, a flash, a light sensor, a proximity sensor, or an iris sensor. Alternatively, the component 20 may function to receive or sense sound. The component area CA may include the transmissive area TA through which light or/and sound, etc. proceeding outward from the component 20 or proceeding inward toward the component 20 from the outside may pass. The transmissive area may thus expand the possible functionality of the component 20.

Referring to FIG. 2, the electronic device 1 may include a display panel 10 and the component 20 disposed under or overlapping the display panel 10.

The display panel 10 may include the substrate 100, a barrier layer 101 disposed on the substrate 100, a display element layer 200 disposed on the barrier layer 101, and a thin-film encapsulation layer 300 arranged on the display element layer 200.

The substrate 100 may include a glass or a polymer resin. The polymer resin may include polyethersulfone (PESU), polyacrylate (PA), polyetherimide (PEI), polyethylene naphthalate (PEN), polyethylene terephthalate (PET), polyphenylene sulfide (PPS), polyarylate (PAR), polyimide (PI), or polycarbonate (PC), etc. The substrate 100 including the polymer resin may have flexible, rollable, or bendable properties. The substrate 100 may be a multi-layer structure including a layer including the polymer resin described above and an inorganic layer.

The display element layer 200 may be disposed on the front surface (or upper surface) of the substrate 100, and a lower protective film BPF may be disposed on the rear surface (or lower surface) of the substrate 100. The lower protective film BPF may be attached to the rear surface (or lower surface) of the substrate. An adhesive layer may be disposed between the lower protective film BPF and the substrate 100. In another embodiment, the lower protective film BPF may be formed directly on the rear surface (or lower surface) of the substrate 100, in which case no adhesive layer may be needed between the lower protective film BPF and the substrate 100.

The lower protective film BPF may support and protect the substrate 100. The lower protective film BPF may be provided with an opening corresponding to the component area CA. The opening in the lower protective film BPF may improve the transmittance of the component area CA, for example, the light transmittance of the transmissive area TA. The lower protective film BPF may include polyethylene terephthalate (PET) or polyimide (PI).

The barrier layer 101 may be disposed on the substrate 100. The barrier layer 101 may reduce or block the infiltration of debris, moisture, or external air. The barrier layer 101 may provide a flat surface on the substrate 100.

The display element layer 200 may be disposed on the barrier layer 101. The display element layer 200 may include a circuit layer including a thin-film transistor TFT, an organic light-emitting diode OLED as a display element, and an insulation layer IL therebetween. In the following embodiments, an organic light-emitting diode is used as a display element, but in another embodiment, an inorganic light-emitting element or a quantum dot light-emitting element may be used as a display element.

A thin-film transistor TFT and an organic light-emitting diode OLED electrically connected to the thin-film transistor TFT may be arranged in the first display area DA1 and the second display area DA2, respectively. In some embodiments, a plurality of first sub-pixels P1 arranged in the first display area DA1 may each include a first organic light-emitting diode OLED1 and a thin-film transistor TFT. The plurality of second sub-pixels P2 arranged in the second display area DA2 may each include a second organic light-emitting diode OLED2 and a thin-film transistor TFT.

The component area CA may include a transmissive area TA in which a thin-film transistor TFT and an organic light-emitting diode OLED are not arranged. The second display area DA2 and the transmissive area TA may be interleaved or arranged alternately within the component area CA.

A bottom metal layer BML may be disposed between the substrate 100 and the barrier layer 101. In some embodiments, the bottom metal layer BML may be disposed on the substrate 100 and the barrier layer 101 may cover the bottom metal layer BML. In another embodiment, the bottom metal layer BML may be inserted within the barrier layer 101.

The bottom metal layer BML may be arranged in the component area CA. In some embodiments, the bottom metal layer BML may be arranged in the second display area DA2 and may define the second display area DA2. In other words, the second display area DA2 may be viewed as the area where the bottom metal layer BML is disposed. In this case, the bottom metal layer BML may include an opening that overlaps the transmissive area TA. For example, an opening in the bottom metal layer BML may define the transmissive area TA. In other words, the transmissive area TA may be viewed as the area that does not contain the bottom metal layer BML.

The bottom metal layer BML may overlap with a thin-film transistor TFT within the component area CA to prevent light and/or sound emitted from the component 20 from reaching the thin-film transistor TFT.

The thin-film encapsulation layer 300 may include at least one inorganic encapsulation layer and at least one organic encapsulation layer. For example, the thin-film encapsulation layer 300 may include a first inorganic encapsulation layer 310, a second inorganic encapsulation layer 330, and an organic encapsulation layer 320 disposed therebetween. The first inorganic encapsulation layer and second inorganic encapsulation layer 310, 330 may include one or more inorganic insulation materials selected from aluminum oxide (AlOₓ), titanium oxide (TiOₓ), tantalum oxide (TaOₓ), hafnium oxide (HfOₓ), zinc oxide (ZnOₓ), silicon oxide (SiOₓ), silicon nitride (SiNₓ), and silicon oxynitride (SiON). The organic encapsulation layer 320 may include at least one or more organic insulation materials selected from polyethylene terephthalate (PET), polyethylene naphthalate (PEN), polycarbonate (PC), polyimide (PI), polyethylene sulfonate (PES), polyoxymethylene (POM), polyarylate (PAR), and hexamethyldisiloxane (HMDSO).

The component 20 may be located in a component area CA. The component 20 may be an electronic element utilizing light or sound. For example, the electronic element may be a sensor that measures distance, such as a proximity sensor, a sensor that recognizes biometrics or a part of the user's body (for example, fingerprint, iris, face, etc.), a small lamp that emits light, or an image sensor (for example, a camera) that captures an image. Electronic elements that utilize light may utilize various wavelength bands of light, including visible light, infrared light, and ultraviolet light. Electronic elements that utilize sound may utilize ultrasound or other frequency bands of sound.

A single component 20 may be arranged in the component area CA, or a plurality of components 20 may be arranged in the component area CA. In some embodiments, the component 20 may include a light-emitter and a light receiver. The light-emitter and light receiver may be physically separate or may be integrated, such that a single component 20 contains both a light-emitter and a light receiver. In some embodiments, the light-emitter may be an infrared transmitter, and the light receiver may be an infrared receiver.

Although not shown in FIG. 2, additional components may be disposed over the display panel 10, such as an input detecting element to detect touch input, an anti-reflective element including a polarizer and retarder or a color filter and a black matrix, and a transparent window.

While FIG. 2 illustrates the use of a thin-film encapsulation layer 300 as a sealing element to seal the display element layer 200, the disclosure is not limited thereto. For example, a sealing substrate that is bound to the substrate 100 by a sealant or frit may be utilized as an element to seal the display element layer 200.

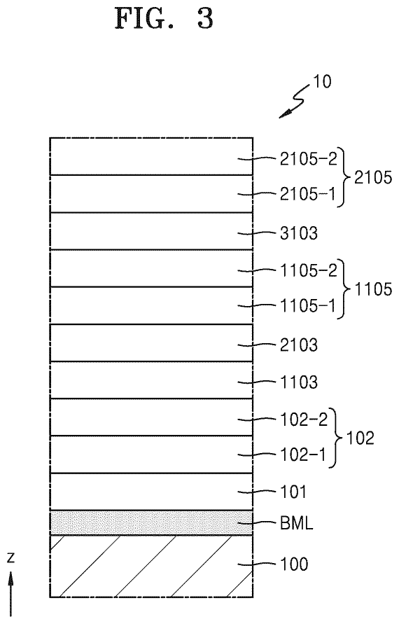

FIG. 3 is an enlarged cross-sectional view illustrating a portion of a display panel according to an embodiment. FIG. 3 may be an enlarged cross-sectional view illustrating area III of FIG. 2.

Referring to FIG. 3, the display panel 10 may include a plurality of inorganic insulation layers disposed over the substrate 100.

A bottom metal layer BML may be disposed on the substrate. The bottom metal layer BML may block light incident from the lower surface of the substrate. The bottom metal layer BML may include a light-shielding material. For example, the bottom metal layer BML may include a light-shielding metal such as chromium (Cr) or molybdenum (Mo), etc.

A barrier layer 101 may be disposed on the bottom metal layer BML. The barrier layer 101 may cover the bottom metal layer BML.

The barrier layer 101 may include an inorganic insulation material including silicon (Si). For example, the barrier layer 101 may include an inorganic insulation material such as silicon oxide (SiOₓ), silicon nitride (SiNₓ), silicon oxynitride (SiON), etc. In some embodiments, the barrier layer 101 may include silicon oxide (SiOₓ).

While FIG. 3 illustrates a lower surface of the bottom metal layer BML and an upper surface of the substrate 100 in direct contact, the disclosure is not limited thereto. In another embodiment, the bottom metal layer BML may be inserted into a barrier layer 101.

A buffer layer 102 may be disposed on the barrier layer 101. The buffer layer 102 may cover the barrier layer 101.

The buffer layer 102 may include an inorganic insulation material including silicon (Si). For example, the buffer layer 102 may include an inorganic insulation material such as silicon oxide (SiOₓ), silicon nitride (SiNₓ), silicon oxynitride (SiON), etc.

The buffer layer 102 may include a first buffer layer 102-1 and a second buffer layer 102-2 disposed on the first buffer layer 102-1. The first buffer layer 102-1 and the second buffer layer 102-2 may include materials that have different refractive indices. In some embodiments, the first buffer layer 102-1 may include silicon nitride (SiNₓ) and the second buffer layer 102-2 may include silicon oxide (SiOₓ).

A first gate insulation layer 1103 may be disposed on the buffer layer 102. The first gate insulation layer 1103 may cover the buffer layer 102. For example, the first gate insulation layer 1103 may be disposed on the second buffer layer 102-2 and may cover the second buffer layer 102-2.

The first gate insulation layer 1103 may include an inorganic insulation material including silicon (Si). For example, the first gate insulation layer 1103 may include an inorganic insulation material such as silicon oxide (SiOₓ), silicon nitride (SiNₓ), silicon oxynitride (SiON), etc.

A second gate insulation layer 2103 may be disposed on the first gate insulation layer 1103. The second gate insulation layer 2103 may cover the first gate insulation layer 1103.

The second gate insulation layer 2103 may include an inorganic insulation material including silicon (Si). For example, the second gate insulation layer 2103 may include an inorganic insulation material such as silicon oxide (SiOₓ), silicon nitride (SiNₓ), silicon oxynitride (SiON), etc.

In some embodiments, the first gate insulation layer 1103 and the second gate insulation layer 2103 may include different materials. For example, the first gate insulation layer 1103 may include silicon oxide (SiOₓ) and the second gate insulation layer 2103 may include silicon nitride (SiNₓ).

A first interlayer insulation layer 1105 may be disposed on the second gate insulation layer 2103. The first interlayer insulation layer 1105 may cover the second gate insulation layer 2103.

The first interlayer insulation layer 1105 may include an inorganic insulation material including silicon (Si). For example, the first interlayer insulation layer 1105 may include an inorganic insulation material such as silicon oxide (SiOₓ), silicon nitride (SiNₓ), silicon oxynitride (SiON), etc.

The first interlayer insulation layer 1105 may include a first-1 interlayer insulation layer 1105-1 and a first-2 interlayer insulation layer 1105-2 disposed on the first-1 interlayer insulation layer 1105-1. The first-1 interlayer insulation layer 1105-1 and the first-2 interlayer insulation layer 1105-2 may include materials that have different refractive indices. In some embodiments, the first-1 interlayer insulation layer 1105-1 may include silicon nitride (SiNₓ) and the first-2 interlayer insulation layer 1105-2 may include silicon oxide (SiOₓ).

A third gate insulation layer 3103 may be disposed on the first interlayer insulation layer 1105. The third gate insulation layer 3103 may cover the first interlayer insulation layer 1105. For example, the third gate insulation layer 3103 may be disposed on the first-2 interlayer insulation layer 1105-2 and cover the first-2 interlayer insulation layer 1105-2.

The third gate insulation layer 3103 may include an inorganic insulation material including silicon (Si). For example, the third gate insulation layer 3103 may include an inorganic insulation material such as silicon oxide (SiOₓ), silicon nitride (SiNₓ), silicon oxynitride (SiON), etc. In some embodiments, the third gate insulation layer 3103 may include silicon oxide (SiOₓ).

A second interlayer insulation layer 2105 may be disposed on the third gate insulation layer 3103. The second interlayer insulation layer 2105 may cover the third gate insulation layer 3103.

The second interlayer insulation layer 2105 may include an inorganic insulation material including silicon (Si). For example, the second interlayer insulation layer 2105 may include an inorganic insulation material such as silicon oxide (SiOₓ), silicon nitride (SiNₓ), silicon oxynitride (SiON), etc.

The second interlayer insulation layer 2105 may include a second-1 interlayer insulation layer 2105-1 and a second-2 interlayer insulation layer 2105-2 disposed on the second-1 interlayer insulation layer 2105-1. The second-1 interlayer insulation layer 2105-1 and the second-2 interlayer insulation layer 2105-2 may include materials that have different refractive indices. In some embodiments, the second-1 interlayer insulation layer 2105-1 may include silicon oxide (SiOₓ) and the second-2 interlayer insulation layer 2105-2 may include silicon nitride (SiNₓ).

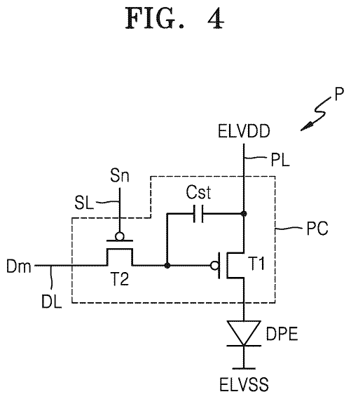

FIG. 4 is an equivalent circuit schematic schematically illustrating a pixel of the display panel.

The display panel 10 as shown in FIG. 2 may include sub-pixels P arranged in the first display area and second display areas DA1 and DA2. The sub-pixel P circuitry shown in FIG. 4 may represent the first sub-pixel or second sub-pixel P1 or P2 described above with reference to FIG. 2.

The sub-pixel P of FIG. 4 may include a sub-pixel circuit PC and a display element DPE connected to the sub-pixel circuit PC. The sub-pixel circuit PC may include a drive thin-film transistor T1, a switching thin-film transistor T2, and a storage capacitor Cst. The sub-pixel P may emit a specific color of light through the display element DPE. For example, the sub-pixel P may emit red, green, or blue light through the display element DPE or may emit red, green, blue, or white light through the display element DPE.

The switching thin-film transistor T2 is connected to both a scan line SL and a data line DL, and may transmit a data voltage or data signal Dm input from the data line DL to the drive thin-film transistor T1 according to a scan voltage or scan signal Sn input from the scan line SL.

The storage capacitor Cst is connected to the switching thin-film transistor T2 and a drive voltage line PL and may store a voltage corresponding to the difference between the voltage received from the switching thin-film transistor T2 and a first power supply voltage ELVDD supplied to the drive voltage line PL.

The drive thin-film transistor T1 is connected to the drive voltage line PL, the storage capacitor Cst, and the display element DPE, and a voltage value stored in the storage capacitor Cst and applied to a gate of the driver thing-film transistor T1 may control the drive current flowing from the drive voltage line PL to the display element DPE. The display element DPE may emit light that has a luminance corresponding to the drive current. A counter electrode (for example, a cathode) of the display element DPE may be supplied with a second power supply voltage ELVSS.

In FIG. 4, a sub-pixel circuit PC is illustrated as including two thin-film transistors and one storage capacitor, but the disclosure is not limited thereto, and the sub-pixel circuit PC may include three or more thin-film transistors.

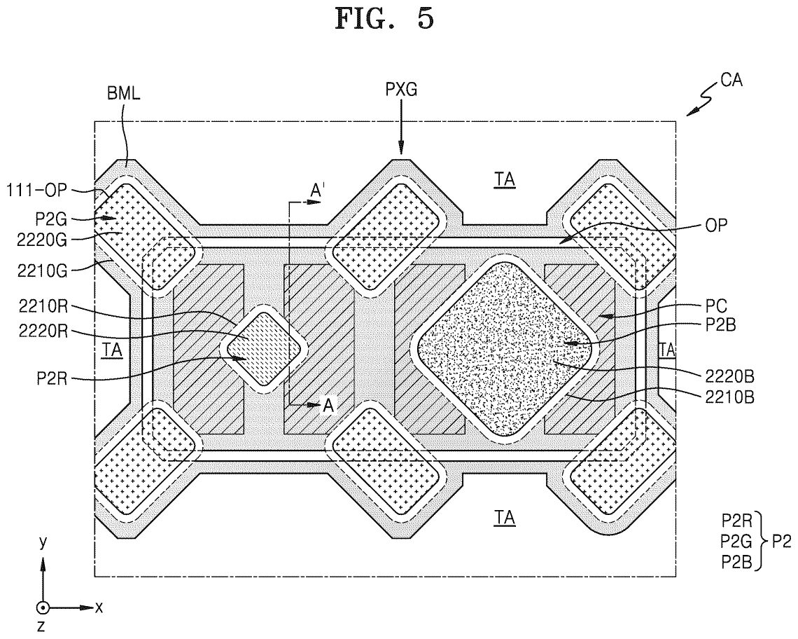

FIG. 5 is an enlarged plan view illustrating a portion of a display panel according to an embodiment.

Referring to FIG. 5, a plurality of second sub-pixels P2 may be arranged in the component area CA. The plurality of second sub-pixels P2 may include, for example, a red second sub-pixel P2R, a green second sub-pixel P2G, and a blue second sub-pixel P2B. The red second sub-pixel P2R, the green second sub-pixel P2G, and the blue second sub-pixel P2B may each have a different size (or area).

The component area CA may include a sub-pixel group PXG including at least one or more second sub-pixels P2 and a transmissive area TA. The arrangement of the sub-pixel group PXG and transmissive area TA within the component area CA is not limited to a specific arrangement and may have various configurations depending on the purpose of the sub-pixel group PXG. In some embodiments, the area not containing the sub-pixel group PXG may be defined as the transmissive area TA as shown in FIG. 5.

The sub-pixel group PXG may be defined as an aggregate of sub-pixels that include a plurality of second sub-pixels P2 grouped in a certain unit. In some embodiments, one sub-pixel group PXG may include eight second sub-pixels P2 arranged in a Pentile® structure, as shown in FIG. 5. For example, one sub-pixel group PXG may include one red second sub-pixel P2R, six green second sub-pixels P2G, and one blue second sub-pixel P2B. Of course, the disclosure is not limited thereto, and the number and colors of the second sub-pixel P2 included in the sub-pixel group PXG may be variously modified. In another embodiment, one sub-pixel group PXG may include a total of seven second sub-pixels P2, including two red second sub-pixels P2R, three green second sub-pixels P2G, and two blue second sub-pixels P2B.

Each second sub-pixel P2 may include a light-emitting diode including a corresponding sub-pixel electrode and an intermediate layer. For example, a red second sub-pixel P2R may include a second-1 sub-pixel electrode 2210R and a second-1 intermediate layer 2220R. The green second sub-pixel P2G may include the second-2 sub-pixel electrode 2210G and the second-2 intermediate layer 2220G. The blue second sub-pixel P2B may include a second-3 sub-pixel electrode 2210B and a second-3 intermediate layer 2220B.

A portion of each intermediate layer (for example, a center portion) may be exposed through an opening of a sub-pixel defining layer 111-OP. Thus, light-emitted by each second sub-pixel P2 may be emitted to the outside through the opening of the sub-pixel defining layer 111-OP. In other words, the openings in a sub-pixel defining layer 111-OP may define the respective light-emitting areas of the second sub-pixels P2.

The sub-pixel circuit PC of a second sub-pixel P2 may be disposed below the second sub-pixel P2 to partially overlap with the second sub-pixel P2. For example, the sub-pixel circuit PC may be arranged to the left and/or right (or, in the −x and/or +x direction) of the red second sub-pixel P2R to partially overlap with the red second sub-pixel P2R and the green second sub-pixel P2G. In addition, the sub-pixel circuit PC may be arranged to the left and/or right (or, in the −x and/or +x direction) of the blue second sub-pixel P2B such that it partially overlaps with the blue second sub-pixel P2B and the green second sub-pixel P2G. In this case, the sub-pixel circuit PC may be electrically connected with each second sub-pixel P2. Of course, the disclosure is not limited thereto, and if the sub-pixel circuit PC may be electrically connected with each second sub-pixel P2, there is no separate limitation on its arrangement location and/or shape.

The bottom metal layer BML may be disposed below the sub-pixel circuit PC such that it overlaps the second sub-pixel P2 and the sub-pixel circuit PC. The area of the bottom metal layer BML may be greater than the sum of the areas of each second sub-pixel P2 and the sub-pixel circuit PC. For example, the red second sub-pixel P2R, the green second sub-pixel P2G, the blue second sub-pixel P2B, and the sub-pixel circuit PC may be arranged within the area covered by the bottom metal layer BML. Thus, when viewed in a plan view, the bottom metal layer BML may appear to protrude from or around the area in which the second subpixel P2 and the sub-pixel circuit PC are arranged. For example, a portion of the bottom metal layer BML may appear to protrude from the area where the green second sub-pixel P2G is arranged, and the bottom metal layer BML may have a shape that wraps around a portion of the green second sub-pixel P2G.

An area where the bottom metal layer BML is arranged may be viewed as the area where the sub-pixel group PXG is arranged. An area where the bottom metal layer BML is not arranged may be viewed as the transmissive area TA.

An insulation layer IL (FIG. 2) described above with reference to FIG. 2 may be disposed over the bottom metal layer BML. A second sub-pixel P2 and a sub-pixel circuit PC may be arranged within the insulation layer IL (FIG. 2). The insulation layer IL (FIG. 2) may include an opening OP formed through at least a portion thereof. In the following, the insulation layer is omitted for ease of description, and the following description focuses on the arrangement and shape of the opening OP.

The opening OP may be in the shape of a groove or trench having a length longer than a width and may be arranged adjacent to the sub-pixel circuit PC. For example, the opening OP may be a closed-loop shape and may surround the sub-pixel circuit PC when viewed in a plan view.

The opening OP may overlap the bottom metal layer BML. In some embodiments, the opening OP may extend along the periphery of the bottom metal layer BML and may be arranged within the area in which the bottom metal layer BML is arranged. The opening OP may be arranged between the transmissive area TA and the sub-pixel circuit PC. In other words, the opening OP may be arranged adjacent to the sub-pixel circuit PC side with respect to the boundary between the transmissive area TA and the bottom metal layer BML. In this case, the opening OP may serve to separate and isolate the transmissive area TA and the sub-pixel circuit PC.

While FIG. 5 illustrates a portion of the opening OP shown to overlap a portion of the green second sub-pixel P2G, the disclosure is not limited thereto. In another embodiment, the opening OP may also surround the green second sub-pixel P2G. For example, in another embodiment, the opening OP may extend along the periphery of the bottom metal layer BML, and a portion of the opening OP may be arranged between the green second sub-pixel P2G and the transmissive area TA. In this case, the opening OP may be arranged adjacent to the green second sub-pixel P2G relative to the boundary between the transmissive area TA and the bottom metal layer BML.

While FIG. 5 illustrates that the shape of the closed-loop of the opening OP is an approximate quadrilateral shape with tapered edges or blunted corners, the disclosure is not limited thereto, and the shape of the closed-loop of the opening OP is not limited as long as it surrounds the sub-pixel circuit PC. In another embodiment, the closed-loop may be variously modified, such as an approximate quadrilateral with rounded corners, oval shape, etc.

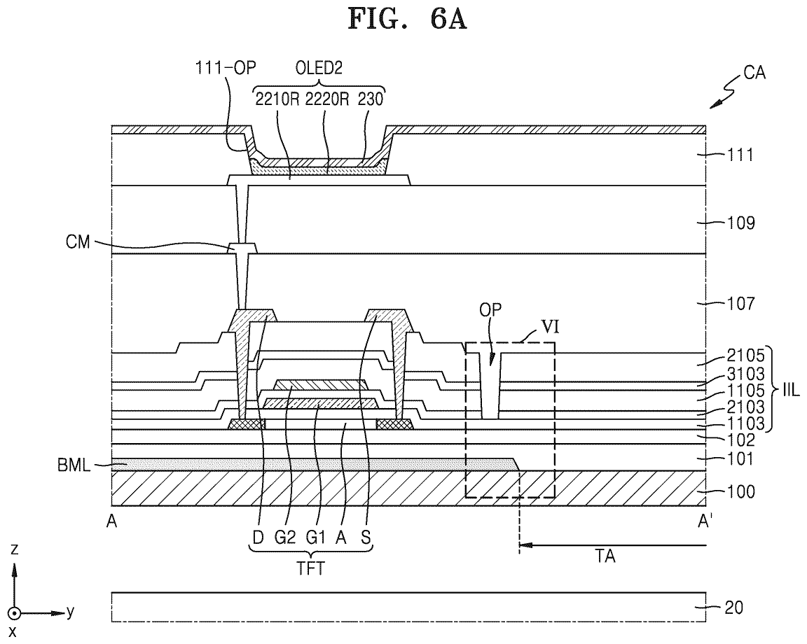

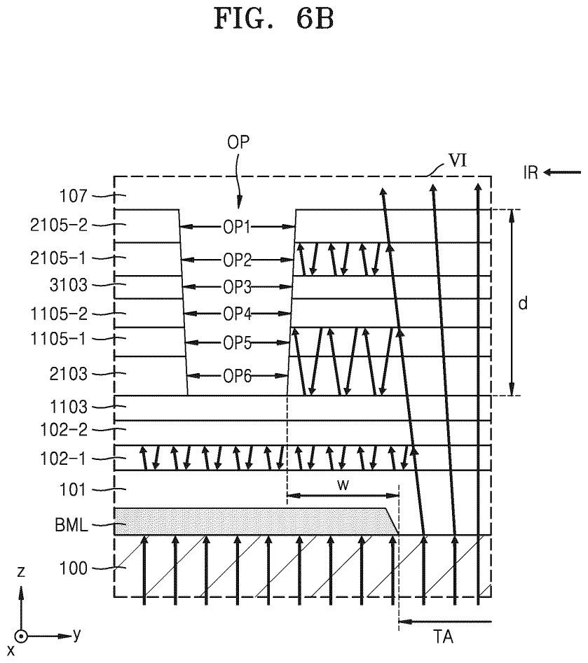

FIG. 6A is a cross-sectional view schematically illustrating a portion of an electronic device including a display panel according to an embodiment. FIG. 6A may be a cross-sectional view taken along lines A-A′ in one of several examples of the embodiment shown in FIG. 5.

A cross-sectional view of the red second sub-pixel is illustrated and described with reference to the red second sub-pixel, but the features described below do not necessarily apply only to the red second sub-pixel.

Referring to FIG. 6A, a second organic light-emitting diode OLED2 corresponding to the second sub-pixel may be disposed over the substrate 100. The second organic light-emitting diode OLED2 may be electrically connected to a thin-film transistor TFT.

On the substrate 100, a bottom metal layer BML and a barrier layer 101 covering the bottom metal layer BML may be disposed. An area in which the bottom metal layer BML is not arranged, for example an area in the +y direction from an edge of the bottom metal layer, may be a transmissive area TA.

A buffer layer 102 may be disposed on the barrier layer 101. The buffer layer 102 as described above with reference to FIG. 3, may be a multi-layer structure including different materials.

A thin-film transistor TFT may be disposed on top of the buffer layer 102. The thin-film transistor TFT may include an active layer A, a first gate electrode G1, a second gate electrode G2, a source electrode S, and a drain electrode D. The thin-film transistor TFT may be connected to the second organic light-emitting diode OLED2 to drive the second organic light-emitting diode OLED2. In some embodiments, the thin-film transistor TFT may correspond to the drive thin-film transistor T1 (FIG. 4) described with reference to FIG. 4. Although not shown in FIG. 6A, other transistors of the pixel circuit such as a switching thin-film transistor T2 (FIG. 4) may also be disposed over the buffer layer 102.

The active layer A may be disposed on the buffer layer 102 and may include a drain area overlapping and electrically connected to the drain electrode D, a source area overlapping and electrically connected to the source electrode S, and a channel area arranged between the drain area and the source area. The drain area and the source area may be doped with impurities. The impurities doped in the drain area and the source area may be different from each other.

The active layer A may overlap the buffer layer 102 and a portion of the barrier layer 101 between the buffer layer and the bottom metal layer BML. The width of the active layer A may be less than the width of the bottom metal layer BML. Thus, when viewed in a plan view (or in the +z direction), the active layer A may overlap the bottom metal layer BML as a whole.

The first gate insulation layer 1103 may be disposed to cover the active layer A. The first gate insulation layer 1103 may include a contact hole overlapping the drain area and a contact hole overlapping the source area.

The first gate electrode G1 may be disposed on the first gate insulation layer 1103. The first gate electrode G1 may overlap the active layer A. The first gate electrode G1 may include aluminum (Al), platinum (Pt), palladium (Pd), silver (Ag), magnesium (Mg), gold (Au), nickel (Ni), neodymium (Nd), iridium (Ir), chromium (Cr), calcium (CA), molybdenum (Mo), titanium (Ti), tungsten (W), and/or copper (Cu), and may be a single-layer or multi-layer structure of any of the materials described above.

The second gate insulation layer 2103 may be disposed to cover the first gate electrode G1. The second gate insulation layer 2103 may include contact holes overlapping the drain area and the source area.

The second gate electrode G2 may be disposed on the second gate insulation layer 2103. The second gate electrode G2 may overlap the first gate electrode G1. The second gate electrode G2 may include aluminum (Al), platinum (Pt), palladium (Pd), silver (Ag), magnesium (Mg), gold (Au), nickel (Ni), neodymium (Nd), iridium (Ir), chromium (Cr), calcium CA, molybdenum (Mo), titanium (Ti), tungsten (W), and/or copper (Cu), and may be a single-layer or multi-layer structure of any of the materials described above.

In some embodiments, the first gate electrode G1 and the second gate electrode G2 overlapping the second gate insulation layer 2103 may form a storage capacitor. For example, the first gate electrode G1 may be integrally formed with the lower electrode of the storage capacitor, and the second gate electrode G2 may be integrally formed with the upper electrode of the storage capacitor. In another embodiment, the lower electrode and/or the upper electrode of the storage capacitor may be formed separately from the first and second gate electrodes G1 and G2.

On the second gate electrode G2 and the second gate insulation layer 2103, the first interlayer insulation layer 1105, the third gate insulation layer 3103, and the second interlayer insulation layer 2105 may be disposed sequentially. The first interlayer insulation layer 1105, the third gate insulation layer 3103, and the second interlayer insulation layer 2105 may each include a contact hole overlapping the drain area and a contact hole overlapping the source area.

A source electrode S and a drain electrode D may be disposed on the second interlayer insulation layer 2105. The source electrode S may be disposed overlapping the source area of the active layer A, and the drain electrode D may be disposed overlapping the drain area of the active layer A.

The source electrode S and the drain electrode D may each be connected to the active layer A through contact holes formed in the first to third gate insulation layers 1103, 2103, and 3103 and the first and second interlayer insulation layers 1105 and 2105. For example, the source electrode S may be connected to the source area of the active layer A through the contact holes formed in the first to third gate insulation layers 1103, 2103, and 3103 and the first and second interlayer insulation layers 1105 and 2105. The drain electrode D may be connected to the drain area of the active layer A through the contact holes formed in the first to third gate insulation layers 1103, 2103, and 3103 and the first and second interlayer insulation layers 1105 and 2105.

The buffer layer 102, the first gate insulation layer to third gate insulation layer 1103, 2103, 3103, and the first interlayer insulation layer and second interlayer insulation layer 1105, 2105 may be viewed as an inorganic insulation layer IIL that includes a plurality of layers.

The inorganic insulation layer IIL may include an opening OP penetrating at least one or more layers of the plurality of layers in the inorganic insulation layer IIL. For example, in FIG. 6A, the inorganic insulation layer IIL may include an opening OP penetrating the second interlayer insulation layer 2105, the third gate insulation layer 3103, the first interlayer insulation layer 1105, and the second gate insulation layer 2103. Alternatively, the opening OP may be formed in the inorganic insulation layer IIL penetrating the second interlayer insulation layer 2105, the third gate insulation layer 3103, the first interlayer insulation layer 1105, and the second gate insulation layer 2103. Thus, the opening OP may be a blind hole penetrating a portion of the inorganic insulation layer IIL.

In this case, the opening OP may overlap with the bottom metal layer BML and may be arranged between the thin-film transistor TFT and the transmissive area. In other words, the opening OP may be arranged between the edges of the thin-film transistor TFT and the bottom metal layer BML.

A first organic insulation layer 107 may be disposed to cover the source electrode S and the drain electrode D. The first organic insulation layer 107 may include contact holes overlapping the drain electrode D.

The first organic insulation layer 107 may include a general-purpose polymer such as benzocyclobutene, polyimide, hexamethyldisiloxane, polymethylmethacrylate, or polystyrene, a polymer derivative that has a phenolic group, an acrylic-based polymer, an imide-based polymer, an aryl ether-based polymer, an amide-based polymer, a fluoro-based polymer, a p-xylene-based polymer, or a vinyl alcohol-based polymer, etc.

A portion of the first organic insulation layer 107 may be arranged within an opening OP of the inorganic insulation layer IIL. The first organic insulation layer 107 may fill at least a portion of the opening OP of the inorganic insulation layer IIL.

A contact metal CM may be disposed on the first organic insulation layer 107. A portion of the contact metal CM may be arranged within a contact hole in the first organic insulation layer 107. The contact metal CM may be connected to the drain electrode D through the contact holes in the first organic insulation layer 107. The contact metal CM may include aluminum (Al), copper (Cu), and/or titanium (Ti), and may consist of a single-layer or multiple layers including any of the materials described above.

A second organic insulation layer 109 may be disposed on the first organic insulation layer 107. The second organic insulation layer 109 may include contact holes overlapping the contact metal CM.

The second organic insulation layer 109 may include a general-purpose polymer such as benzocyclobutene, polyimide, hexamethyldisiloxane, polymethylmethacrylate, or polystyrene, a polymer derivative that has a phenolic group, an acrylic-based polymer, an imide-based polymer, an aryl ether-based polymer, an amide-based polymer, a fluoro-based polymer, a p-xylene-based polymer, or a vinyl alcohol-based polymer, etc.

The second-1 sub-pixel electrode 2210R may be disposed on the second organic insulation layer 109. The second-1 sub-pixel electrode 2210R may be connected to the contact metal CM through contact holes formed in the second organic insulation layer 109. Thus, the second-1 sub-pixel electrode 2210R may be electrically connected to the thin-film transistor TFT through both the contact metal CM and the drain electrode D.

The second-1 sub-pixel electrode 2210R may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The second-1 sub-pixel electrode 2210R may include a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. For example, the second-1 sub-pixel electrode 2210R may have a structure with films formed of ITO, IZO, ZnO, or In₂O₃ on one or both sides of the reflective film described above. Of course, the configuration and materials of the second-1 sub-pixel electrode 2210R are not limited thereto, and various modifications are possible.

While FIG. 6A illustrates one contact metal and two organic insulation layers 107 and 109, the disclosure is not limited thereto. In another embodiment, the organic insulation layer may be a single-layer, the contact metal may be omitted, and the second-1 sub-pixel electrode 2210R may be directly connected to the drain electrode D. Alternatively, the organic insulation layer may include three or more layers, and the contact metal may be provided in plurality.

A sub-pixel defining layer 111 may be disposed on the second organic insulation layer 109. The sub-pixel defining layer 111 may cover an edge (or edge area) of the second-1 sub-pixel electrode 2210R. In other words, the sub-pixel defining layer 111 may include an opening 111-OP that exposes a center portion of the second-1 sub-pixel electrode 2210R. The size and shape of the light-emitting area of the second organic light-emitting diode OLED2 may be defined by the opening 111-OP in the sub-pixel defining layer 111.

The second-1 intermediate layer 2220R may be disposed on the second-1 sub-pixel electrode 2210R within the opening 111-OP in the sub-pixel defining layer 111. The second-1 intermediate layer 2220R may include an organic emission layer EML including a small molecular material or polymeric material. The second-1 intermediate layer 2220R may have a single or multi-layer structure stacked with a hole injection layer (HIL), a hole transport layer (HTL), an organic emission layer (EML), an electron transport layer (ETL), and/or an electron injection layer (EIL), etc.

Counter electrodes 230 may be disposed on the second-1 intermediate layer 2220R. The counter electrodes 230 may be arranged or may extend throughout the component area CA.

The counter electrode 230 may be formed as a transparent/translucent electrode. When the counter electrode 230 is formed as a transparent/translucent electrode, it may include silver (Ag), aluminum (Al), magnesium (Mg), lithium (Li), calcium CA, copper (Cu), or a compound or alloy including any of these. Of course, the composition and materials of the counter electrode 230 are not limited thereto, and various modifications are possible.

Although not shown in FIG. 6A, a thin-film encapsulation layer 300 (FIG. 2) may be disposed on the counter electrode 230.

FIG. 6B is an enlarged cross-sectional view schematically illustrating a portion of an electronic device including a display panel according to an embodiment. FIG. 6B may be an enlarged cross-sectional view illustrating an area VI of FIG. 6A.

Referring to FIG. 6B, in an embodiment, an opening OP may be formed penetrating the second-2 interlayer insulation layer 2105-2, the second-1 interlayer insulation layer 2105-1, the third gate insulation layer 3103, the first-2 interlayer insulation layer 1105-2, the first-1 interlayer insulation layer 1105-1, and the second gate insulation layer 2103.

The opening OP may include portions respectively corresponding to the formed layers. In the example of FIG. 6B, a first portion OP1 of the opening OP may penetrate the second-2 interlayer insulation layer 2105-2. A second portion OP2 of the opening OP may penetrate the second-1 interlayer insulation layer 2105-1. A third portion OP3 of the opening OP may penetrate the third gate insulation layer 3103. A fourth portion OP4 of the opening OP may penetrate the first-2 interlayer insulation layer 1105-2. A fifth portion OP5 of the opening OP may penetrate the first-1 interlayer insulation layer 1105-1. A sixth portion OP6 of the opening OP may penetrate the second gate insulation layer 2103.

In some embodiments, the width of the opening OP may increase toward the +z direction. In another embodiment, the width of the opening OP may be constant.

The opening OP may be at least partially filled by the first organic insulation layer 107.

A horizontal distance w from an edge of the bottom metal layer BML to the opening OP may be greater than the depth of the opening OP. In some embodiments, unlike shown in FIG. 6B, the horizontal distance w from an edge of the bottom metal layer BML to one side of the opening OP adjacent to the edge of the bottom metal layer BML may be greater than the depth d of the opening OP. For example, the horizontal distance w may be about 4 micrometers (μm), and the depth d may be about 1 micrometer (μm) to about 2 micrometers (μm).

The bottom metal layer BML and the opening OP may serve to block various types of light. The bottom metal layer BML and opening OP may block light incident from up and down (or +z direction), forward and backward (or +x direction), and/or left and right (or ty direction). However, for ease of description, the following illustrates and describes the case where light initially propagates or proceeds from the bottom toward the top (or along the +z direction) of the area VI. This example may correspond to light originating in a component 20 (FIG. 6A) underlying the substrate 100.

Light proceeding upward in the area overlapping the bottom metal layer BML may pass through the substrate 100, but the bottom metal layer BML on the substrate 100 blocks that light, and the light cannot proceed further in the +z direction. Thus, direct light directed upward at the thin-film transistor may be blocked by the bottom metal layer BML.

Light proceeding into the transmissive area TA may pass through the substrate 100 and the barrier layer 101. In this case, the bottom metal layer BML acts as an obstacle and the transmissive area TA as a slit, and diffraction of the proceeding light may occur.

Therefore, the proceeding path of some of the light that was propagating parallel to the +z direction may deflect and proceed at a non-zero angle to the +z direction. Thus, light proceeding or propagating in the transmissive area TA may have a range of angles of incidence for each layer of the inorganic insulation layer in its proceeding path.

Each layer of the inorganic insulation layer in the path of the light may include different materials, and the refractive index in each layer may be different. Therefore, if the angle of incidence of the proceeding light when proceeding from one layer to another layer is greater than the critical angle, total internal reflection of the proceeding light may occur. For example, if the component 20 is an infrared sensor or source, the proceeding light may be an infrared light. In this case, total internal reflection due to the difference in refractive index may occur particularly frequently at the interface between silicon oxide (SiOₓ)-silicon nitride (SiNₓ) and/or the interface between silicon oxide (SiOₓ)-silicon nitride (SiNₓ)-silicon oxide (SiOₓ).

The light that has undergone total internal reflection may proceed left and right (or +y direction) along the layer in which total internal reflection has occurred.

In some embodiments, light proceeding at a non-zero angle with respect to the +z direction in the transmissive area TA may be totally reflected at the interface of the first buffer layer 102-1 and the second buffer layer 102-2 and proceed in the −y direction along the first buffer layer 102-1.

In some embodiments, light proceeding at a non-zero angle with respect to the +z direction may be totally reflected at the interface of the first-1 interlayer insulation layer 1105-1 and the first-2 interlayer insulation layer 1105-2 and proceed in the −y direction along the first-1 interlayer insulation layer 1105-1 and the second gate insulation layer 2103.

In some embodiments, light proceeding at a non-zero angle with respect to the +z direction may be totally reflected at the interface of the second-1 interlayer insulation layer 2105-1 and the second-2 interlayer insulation layer 2105-2 and proceed in the −y direction along the second-1 interlayer insulation layer 2105-1.

If the light proceeding in the −y direction is not blocked, the proceeding light may reach the thin-film transistor. This may cause performance degradation of the thin-film transistor and lead to deterioration of image quality on the display panel. To prevent this, blocking the path of proceeding light that is totally reflected or preventing total internal reflection in advance is required.

According to an embodiment, the opening OP may prevent the light from proceeding in the −y direction or prevent the light from being totally reflected at all. For example, the opening OP may remove a portion of a layer including the silicon nitride (SiNₓ) to block the path of the proceeding light or to prevent total internal reflection.

In some embodiments, the second portion OP2 of the opening OP may prevent light proceeding along the second-1 interlayer insulation layer 2105-1 from proceeding in the −y direction.

In some embodiments, the fifth portion and sixth portion OP5, OP6 of the opening OP may prevent light proceeding along the first-1 interlayer insulation layer 1105-1 and the second gate insulation layer 2103 from proceeding in the −y direction.

In FIG. 6B, light proceeding along the first buffer layer 102-1, the first-1 interlayer insulation layer 1105-1, the second gate insulation layer 2103, and the second-1 interlayer insulation layer 2105-1 are each shown extending from the same light propagating at the same angle relative to the +z direction. However, this should not be understood as showing that only part of the corresponding light is reflected and proceeds along each layer. Rather, it is to be understood that all of the light may at particular angles may be reflect and interfaces between layers and proceed along the first buffer layer 102-1, proceed along the first-1 interlayer insulation layer 1105-1 and the second gate insulation layer 2103, or proceed along the second-1 interlayer insulation layer 2105-1. This is also true in the following drawings.

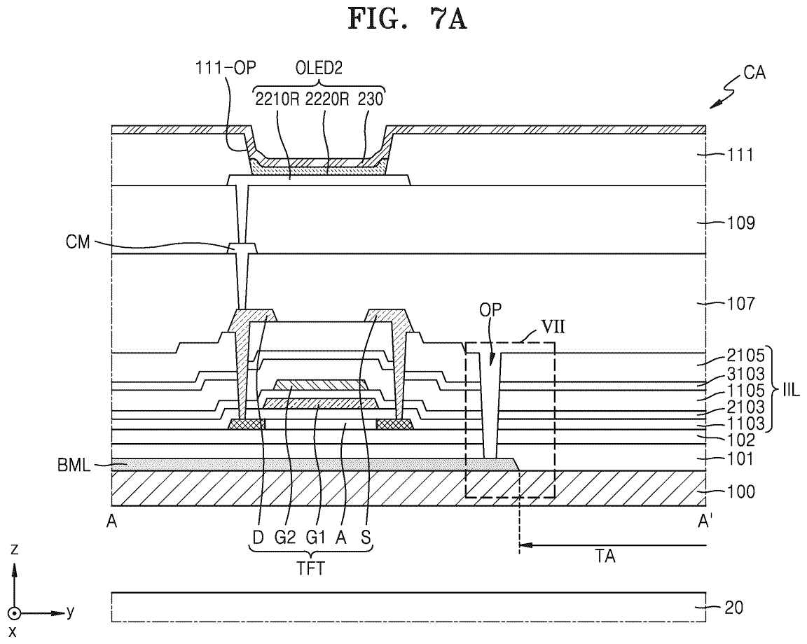

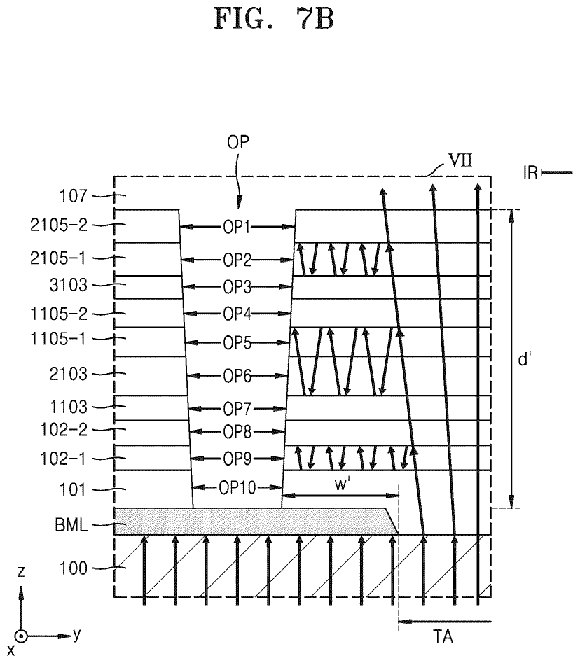

FIG. 7A is a cross-sectional view schematically illustrating a portion of an electronic device including a display panel according to an embodiment. FIG. 7A may be a cross-sectional view of the display panel taken along lines A-A′ in one of several examples of the embodiment shown in FIG. 5.

Referring to FIG. 7A, the opening OP in the inorganic insulation layer IIL may be a penetration hole penetrating the inorganic insulation layer IIL. In some embodiments, the opening OP may penetrate the second interlayer insulation layer 2105, the third gate insulation layer 3103, the first interlayer insulation layer 1105, the second gate insulation layer 2103, and the first gate insulation layer 1103. Additionally, the opening OP may extend through portions of the buffer layer 102 and the barrier layer 101 to expose a portion of the bottom metal layer BML. In other words, the opening OP may extend to the upper surface of the bottom metal layer BML.

A portion of the first organic insulation layer 107 may be within the opening OP, and a portion of the first organic insulation layer 107 may be in contact with the bottom metal layer BML.

FIG. 7B is an enlarged cross-sectional view schematically illustrating a portion of an electronic device including a display panel according to an embodiment. FIG. 7B may be an enlarged cross-sectional view illustrating area VII of FIG. 7A.

Referring to FIG. 7B, an opening OP may be formed penetrating the second-2 interlayer insulation layer 2105-2, second-1 interlayer insulation layer 2105-1, third gate insulation layer 3103, first-2 interlayer insulation layer 1105-2, first-1 interlayer insulation layer 1105-1, second gate insulation layer 2103, first gate insulation layer 1103, second buffer layer 102-2, and first buffer layer 102-1, and barrier layer 101.

The opening OP may include a portion corresponding to each of the formed layers.

In some embodiments, a first portion OP1 of the opening OP may penetrate the second-2 interlayer insulation layer 2105-2. A second portion OP2 of the opening OP may penetrate the second-1 interlayer insulation layer 2105-1. A third portion OP3 of the opening OP may penetrate the third gate insulation layer 3103. A fourth portion OP4 of the opening OP may penetrate the first-2 interlayer insulation layer 1105-2. A fifth portion OP5 of the opening OP may penetrate the first-1 interlayer insulation layer 1105-1. A sixth portion OP6 of the opening OP may penetrate the second gate insulation layer 2103. A seventh portion OP7 of the opening OP may penetrate the first gate insulation layer 1103. An eighth portion OP8 of the opening OP may penetrate the second buffer layer 102-2. A ninth portion OP9 of the opening OP may penetrate the first buffer layer 102-1. A tenth portion OP10 of the opening OP may be formed in the barrier layer 101.

The opening OP may be at least partially filled by the first organic insulation layer 107. Thus, the first organic insulation layer 107 may be in contact with the bottom metal layer BML.

The horizontal distance from an edge of the bottom metal layer BML to the opening OP may be greater than the depth of the opening OP. In some embodiments, unlike shown in FIG. 7B, the horizontal distance w′ from an edge of the bottom metal layer BML to one side of the opening OP adjacent to the edge of the bottom metal layer BML may be greater than the depth d′ of the opening OP. For example, the horizontal distance w′ may be about 4 micrometers (μm), and the depth d′ may be about 1 micrometer (μm) to about 2 micrometers (μm).

The opening OP may prevent light from proceeding in the −y direction.

In some embodiments, a second portion OP2 of the opening OP may prevent light proceeding along the second-1 interlayer insulation layer 2105-1 from proceeding in the −y direction.

The fifth portion and sixth portion OP5, OP6 of the opening OP may prevent light proceeding along the first-1 interlayer insulation layer 1105-1 and the second gate insulation layer 2103 from proceeding in the −y direction.

A ninth portion OP9 of the opening OP may prevent light proceeding along the first buffer layer 102-1 from proceeding in the −y direction.

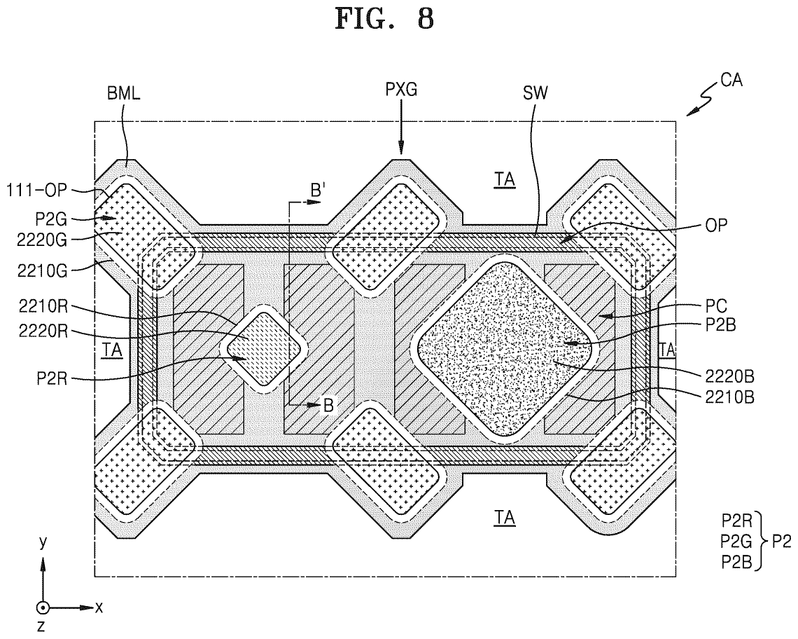

FIG. 8 is an enlarged plan view illustrating a portion of a display panel according to another embodiment.

A shielding layer SW, which may contain a metallic material, may fill at least a portion of the opening OP. A portion of the shielding layer SW may be arranged within the opening OP, and a portion may be disposed on an inorganic insulation layer IIL outside the opening OP. The width of the shielding layer may be the same as the width of the opening OP or greater than the width of the opening OP.

A planar shape of the shielding layer SW may be similar to the opening. The shielding layer SW may be in the shape of a groove or trench with a length greater than a width and may be in the shape of a closed circuit surrounding the sub-pixel circuits PC.

The shielding layer SW may overlap the bottom metal layer BML. In some embodiments, the shielding layer SW may extend along the periphery of the bottom metal layer BML and may be arranged within the area in which the bottom metal layer BML is arranged. The shielding layer SW may be between the transmissive area TA and the sub-pixel circuits PC. In other words, the shielding layer SW may be arranged adjacent to the sub-pixel circuits PC on sides nearest to the boundary between the transmissive area TA and the bottom metal layer BML. In this case, the shielding layer SW may serve to separate and isolate the transmissive area TA and the sub-pixel circuit PC.

While FIG. 8 illustrates a portion of the shielding layer SW overlapping a portion of the green second sub-pixel P2G, the disclosure is not limited thereto. In another embodiment, the shielding layer SW may also surround the green second sub-pixel P2G. For example, in another embodiment, the shielding layer SW may extend along the periphery of the bottom metal layer BML, and a portion of the shielding layer SW may be arranged between the green second sub-pixel P2G and the transmissive area TA. In this case, the shielding layer SW may be adjacent to the green second sub-pixel P2G relative to the boundary between the transmissive area TA and the bottom metal layer BML.

While FIG. 8 illustrates that the shape of the closed-loop of the shielding layer SW is an approximate quadrilateral shape with blunted corners, the disclosure is not limited thereto, and the shape of the closed-loop of the shielding layer SW is not limited as long as it surrounds the sub-pixel circuit PC being protected. In another embodiment, the closed-loop may be variously modified, such as an approximate quadrilateral with rounded corners, oval shape, etc.

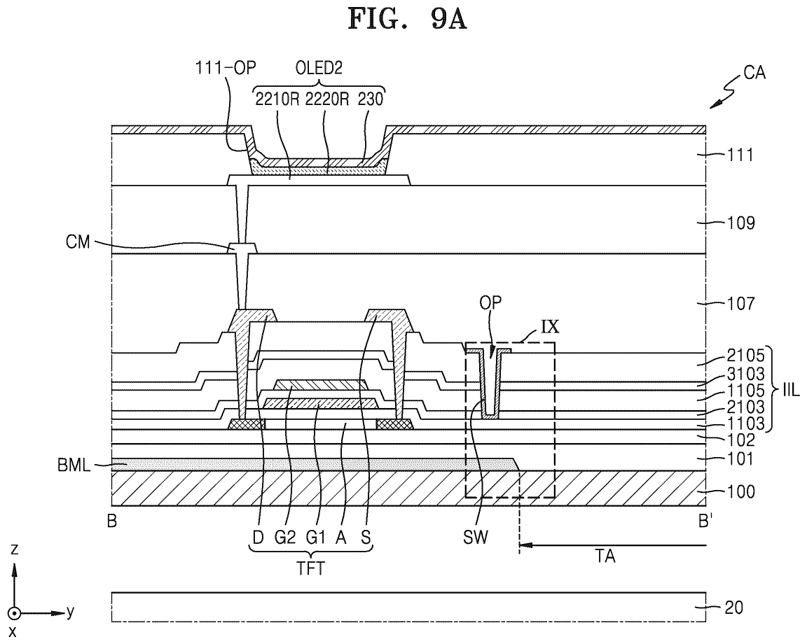

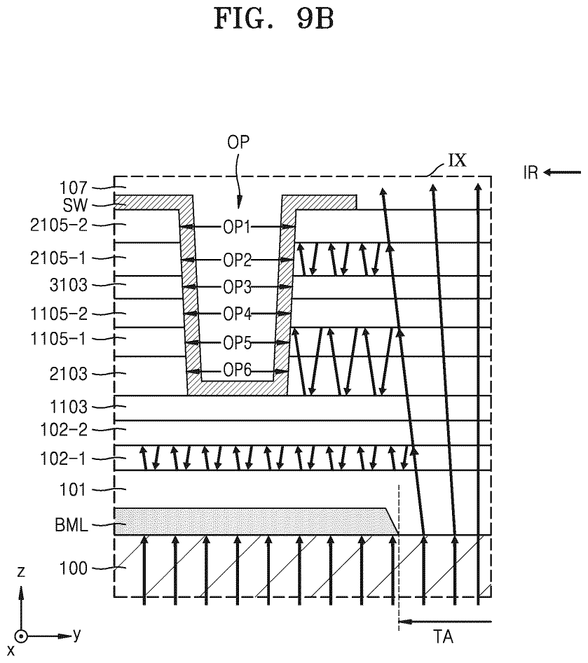

FIG. 9A is a cross-sectional view schematically illustrating a portion of an electronic device including a display panel according to another embodiment. FIG. 9A may be a cross-sectional view of the display panel taken along lines B-B′ in one of several examples of the embodiment shown in FIG. 8.

The embodiment shown in FIG. 9A may be viewed as being the same as the embodiment described above with reference to FIG. 6A but with the addition of a shielding layer SW.

The shielding layer SW may fill at least a portion of the opening OP. A portion of the shielding layer SW may be arranged within the opening OP, and a portion may be disposed on the inorganic insulation layer IIL outside the opening OP.

The shielding layer SW may cover a portion of the opening OP. For example, the shielding layer SW may cover an inner surface of the inorganic insulation layer IIL in which the opening OP is formed. The shielding layer SW may also cover a bottom of the opening OP, i.e., a portion of the first gate insulation layer 1103.

A portion of the opening OP not filled by the shielding layer SW may be at least partially filled by the first organic insulation layer 107. Alternatively, the shielding layer SW may fill the opening OP.

The shielding layer SW may include a light-shielding material. For example, the shielding layer SW may include a light-shielding metal such as chromium (Cr) or molybdenum (Mo).

FIG. 9B is an enlarged cross-sectional view schematically illustrating a portion of an electronic device including a display panel according to another embodiment. FIG. 9B may be an enlarged cross-sectional view illustrating area IX of FIG. 9A.

The embodiment shown in FIG. 9B may be viewed as the embodiment described above with reference to FIG. 6B but with the addition of a shielding layer SW.

The shielding layer SW may cover an inner surface of the layer in which the opening OP is formed. For example, the shielding layer SW may cover the inner side surfaces of the second-2 interlayer insulation layer 2105-2, the second-1 interlayer insulation layer 2105-1, the third gate insulation layer 3103, the first-2 interlayer insulation layer 1105-2, the first-1 interlayer insulation layer 1105-1, and the second gate insulation layer 2103.

The shielding layer SW may cover a portion of a layer in which an opening OP is formed and a portion of the upper surface that opening OP exposes. For example, the shielding layer SW may cover a portion of the first gate insulation layer 1103 exposed by the opening OP.

The shielding layer SW may prevent light from proceeding in the −y direction.

In some embodiments, a portion of the shielding layer SW arranged in the second portion OP2 of the opening OP may prevent light proceeding along the second-1 interlayer insulation layer 2105-1 from proceeding in the −y direction.

A portion of the shielding layer SW arranged in the fifth and sixth portions OP5 and OP6 may prevent light proceeding along the first-1 interlayer insulation layer 1105-1 and the second gate insulation layer 2103 from proceeding in the −y direction.

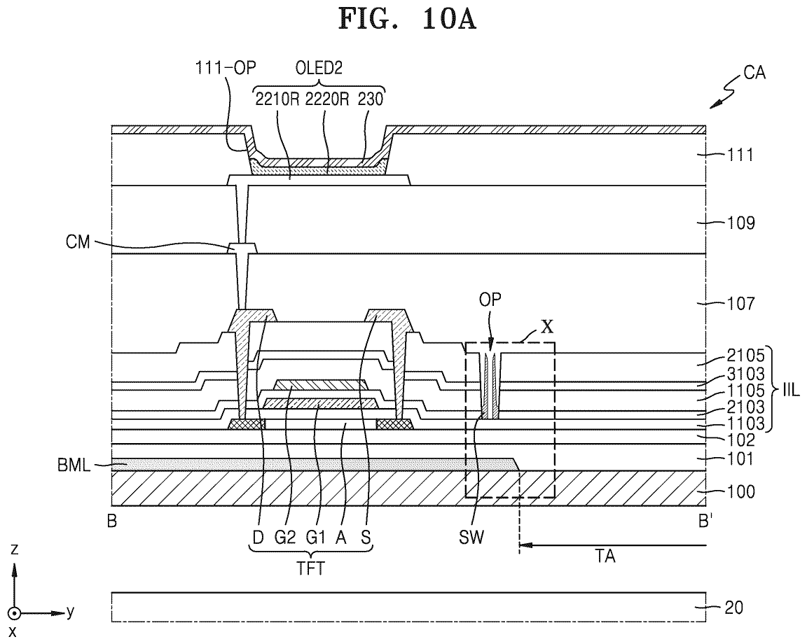

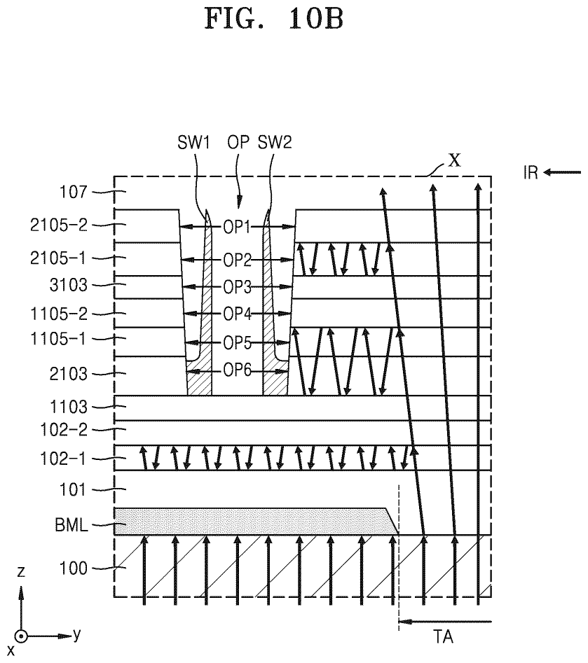

FIG. 10A is a cross-sectional view schematically illustrating of a portion of an electronic device including a display panel according to another embodiment. FIG. 10A may be a cross-sectional view of the display panel taken along lines B-B′ in one of several examples of the embodiment shown in FIG. 8.

The embodiment shown in FIG. 10A may be viewed as being substantially the same as the embodiment described with reference to FIG. 6A but with the addition of a shielding layer SW as shown in FIG. 10A.

The shielding layer SW may be arranged within the opening OP and may fill at

least a portion of the opening OP. In the embodiment of FIG. 10A, the shielding layer SW may be in the form of a stringer extending in the +z direction with a bottom end of the stringer secured to the bottom of the opening OP. A portion of the stringer in the shielding layer SW may be in contact with a portion of the inner surface of the inorganic insulation layer IIL in which the opening OP is formed. Also, a portion of the stringer in the shielding layer SW may be spaced apart from a portion of the inner surface of the inorganic insulation layer IIL in which the opening OP is formed.

FIG. 10B is an enlarged cross-sectional view schematically illustrating a portion of an electronic device including a display panel according to another embodiment. FIG. 10B may be an enlarged cross-sectional view illustrating area X of FIG. 10A.

The embodiment shown in FIG. 10B may be viewed as being substantially the same as the embodiment shown in FIG. 6B but with the addition of a shielding layer SW including a first shielding layer SW1 and a second shielding layer SW2 as shown in FIG. 10B.

The first shielding layer SW1 and the second shielding layer SW2 may be stringers arranged on either side of the opening OP. For example, the first shielding layer SW1 may be arranged on a left (or −y direction) portion of the opening OP, and the second shielding layer SW2 may be arranged on a right (or +y direction) portion of the opening OP.

A lower surface of the first shielding layer and second shielding layer SW1, SW2 may contact the first gate insulation layer 1103 and cover a portion of the first gate insulation layer 1103. A portion of the upper surface of the first gate insulation layer 1103 may be exposed through the space between the first shielding layer and second shielding layer SW1, SW2. A portion of the opening OP in which the first shielding layer and second shielding layer SW1, SW2 do not occupy may be at least partially filled with the first organic insulation layer 107. Thus, a portion of the upper surface of the first gate insulation layer 1103 may be covered by the first organic insulation layer 107.

A portion of some of the sides of the first and second shielding layers SW1 and SW2 may be in contact with an inner wall of the inorganic insulation layer in which the opening OP is formed. For example, a portion of the side facing the −y direction of the first shielding layer SW1 may be in contact with the inner walls of the second gate insulation layer 2103 and the first-1 interlayer insulation layer 1105-1 facing the +y direction. A portion of the side facing the +y direction of the second shielding layer SW2 may be in contact with the inner walls of the second gate insulation layer 2103 and the first-1interlayer insulation layer 1105-1 facing the −y direction.

Other portions of the side of the first and second shielding layers SW1 and SW2 may be spaced apart from the inner wall of the inorganic insulation layer in which the opening OP is formed. For example, a portion of the side facing the −y direction of the first shielding layer SW1 may be spaced apart from the inner wall of the first-2 interlayer insulation layer 1105-2, the third gate insulation layer 3103, the second-1 interlayer insulation layer 2105-1, and the second-2 interlayer insulation layer 2105-2 facing the +y direction. Other portions of facing the +y direction of the second shielding layer SW2 may be spaced apart from the inner wall of the first-2 interlayer insulation layer 1105-2, the third gate insulation layer 3103, the second-1 interlayer insulation layer 2105-1, and the second-2 interlayer insulation layer 2105-2 facing the −y direction.

Of course, the contact range between one side of the first shielding layer and second shielding layer SW1, SW2 and the inner wall of the inorganic insulation layer may be variously changed.

The first and second shielding layers SW1 and SW2 may prevent light from proceeding in the −y direction.

In some embodiments, a portion of the first and second shielding layers SW1 and SW2 in the second portion OP2 may prevent light proceeding along the second-1interlayer insulation layer 2105-1 from proceeding in the −y direction.

A portion of the first and second shielding layers SW1 and SW2 arranged in the fifth portion and sixth portion OP5, OP6 may prevent light proceeding along the first-1 interlayer insulation layer 1105-1 and the second gate insulation layer 2103 from proceeding in the −y direction.

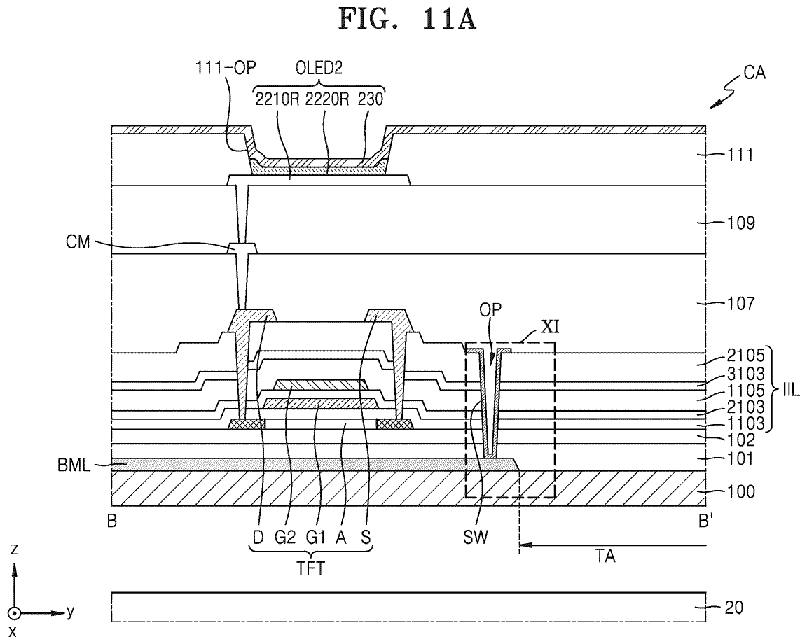

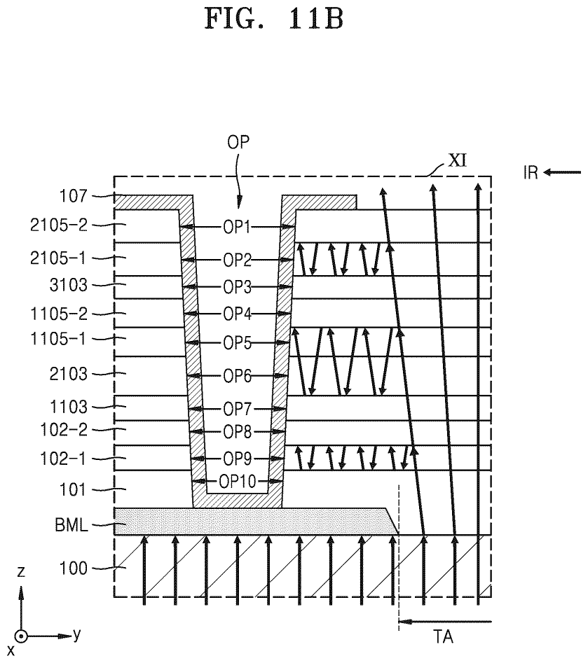

FIG. 11A is a cross-sectional view schematically illustrating a portion of an electronic device including a display panel according to another embodiment. FIG. 11A may be a cross-sectional view of the display panel taken along lines B-B′ in one of several examples of the embodiment shown in FIG. 8.

The embodiment shown in FIG. 11A may be viewed as being substantially the same as the embodiment shown in FIG. 7A but with addition of a shielding layer SW as shown in FIG. 11A.

The shielding layer SW may fill at least a portion of the opening OP. A portion of the shielding layer SW may be arranged within the opening OP, and a portion may be disposed on an inorganic insulation layer IIL outside the opening OP.

The shielding layer SW may cover a portion of the opening OP. For example, the shielding layer SW may cover an inner surface of the inorganic insulation layer IIL in which the opening OP is formed. The shielding layer SW may cover a lower surface of the inorganic insulation layer IIL in which the opening OP is formed.

A portion of the opening OP not filled by the shielding layer SW may be at least partially filled by the first organic insulation layer 107. In an embodiment, the shielding layer SW may be formed to fill all openings OP.

Since a portion of the upper surface of the bottom metal layer BML may be exposed by the opening OP, the shielding layer SW and the bottom metal layer BML may be in direct contact.

FIG. 11B is an enlarged cross-sectional view schematically illustrating a portion of an electronic device including a display panel according to another embodiment. FIG. 11B may be an enlarged cross-sectional view illustrating area XI of FIG. 11A.

Referring to FIG. 11B, the embodiment shown in FIG. 11B may be viewed as an embodiment of the embodiment shown in FIG. 7B with a shielding layer SW.

The shielding layer SW may cover an inner surface of the layer in which the opening OP is formed. For example, the shielding layer SW may cover the inner surface of the second-2 interlayer insulation layer 2105-2, the second-1 interlayer insulation layer 2105-1, the third gate insulation layer 3103, the first-2 interlayer insulation layer 1105-2, the first-1 interlayer insulation layer 1105-1, and the second gate insulation layer 2103, the first gate insulation layer 1103, the second buffer layer 102-2, the first buffer layer 102-1, and the barrier layer 101.

The shielding layer SW may cover a portion of a layer in which an opening OP is formed and a portion of the upper surface is exposed. For example, the shielding layer SW may cover a portion of the upper surface of the bottom metal layer BML exposed by the opening OP. Both the bottom metal layer BML and the shielding layer SW may include metal. A constant voltage or signal may be applied to the bottom metal layer BML to prevent damage to the thin-film transistors disposed on the top of the bottom metal layer BML by electrostatic discharge etc. Therefore, the voltage or signal applied to the bottom metal layer BML may also be applied to the shielding layer SW.

The shielding layer SW may prevent light from proceeding in the −y direction.

In some embodiments, a portion of the shielding layer SW arranged in the second portion OP2 may prevent light proceeding along the second-1 interlayer insulation layer 2105-1 from proceeding in the −y direction.

A portion of the shielding layer SW arranged in the fifth and sixth portions OP5 and OP6 may prevent light proceeding along the first-1 interlayer insulation layer 1105-1 and the second gate insulation layer 2103 from proceeding in the −y direction.

A portion of the shielding layer SW arranged in the ninth portion OP9 may prevent light proceeding along the first buffer layer 102-1 from proceeding in the −y direction.

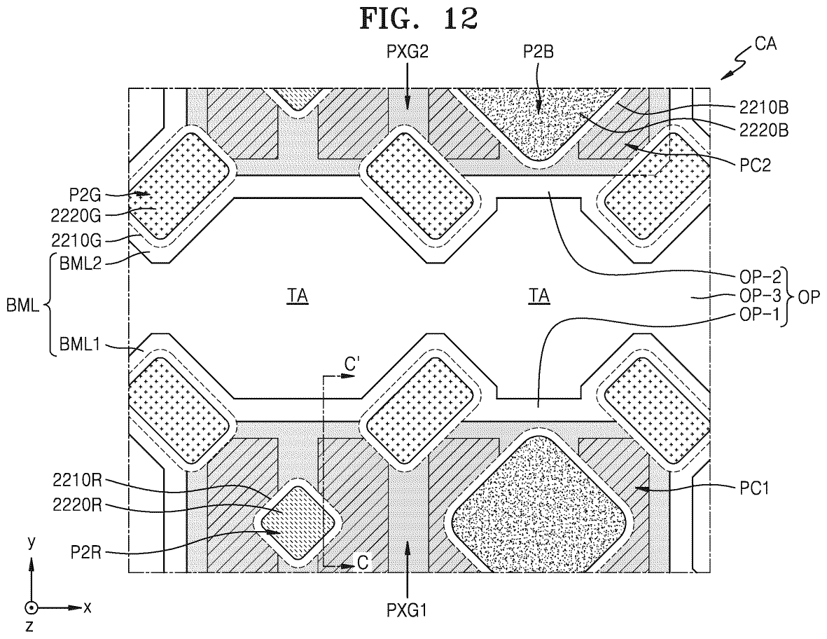

FIG. 12 is an enlarged plan view illustrating a portion of a display panel according to another embodiment.

Referring to FIG. 12, a plurality of sub-pixel groups may be arranged in the component area CA. For example, a first sub-pixel group PXG1 and a second sub-pixel group PXG2 adjacent to the first sub-pixel group PXG1 may be arranged in the component area CA.

The first sub-pixel group PXG1 may include a first sub-pixel circuit PC1 and a first bottom metal layer BML1. The second sub-pixel group PXG2 may include a second sub-pixel circuit PC2 and a second bottom metal layer BML2.

An opening OP in FIG. 12 may include first to third openings OP-1, OP-2, and OP-3. The first opening OP-1 surrounds the first sub-pixel circuit PC1 and may be disposed overlapping the first bottom metal layer BML1. The second opening OP-2 surrounds the second sub-pixel circuit PC2 and may be disposed overlapping the second bottom metal layer BML2. A third opening OP-3 may be disposed between the first opening and second opening OP-1, OP-2 and may overlap the transmissive area TA.

The first to third openings OP-1, OP-2, and OP-3 may be integral. Therefore, the portion of one opening OP that overlaps the first bottom metal layer BML1 may be understood as the first opening OP-1, the portion that overlaps the second bottom metal layer BML2 may be understood as the second opening OP-2, and the portion that overlaps the transmissive area TA may be understood as the third opening OP-3.

In this case, the transmissive area TA may be viewed as a space arranged between the first and second bottom metal layers BML1 and BML2. Alternatively, the first and second bottom metal layers BML1 and BML2 may be viewed as portions of a single bottom metal layer BML, and the transmissive area TA may be viewed as an area corresponding to an opening through the bottom metal layer BML.

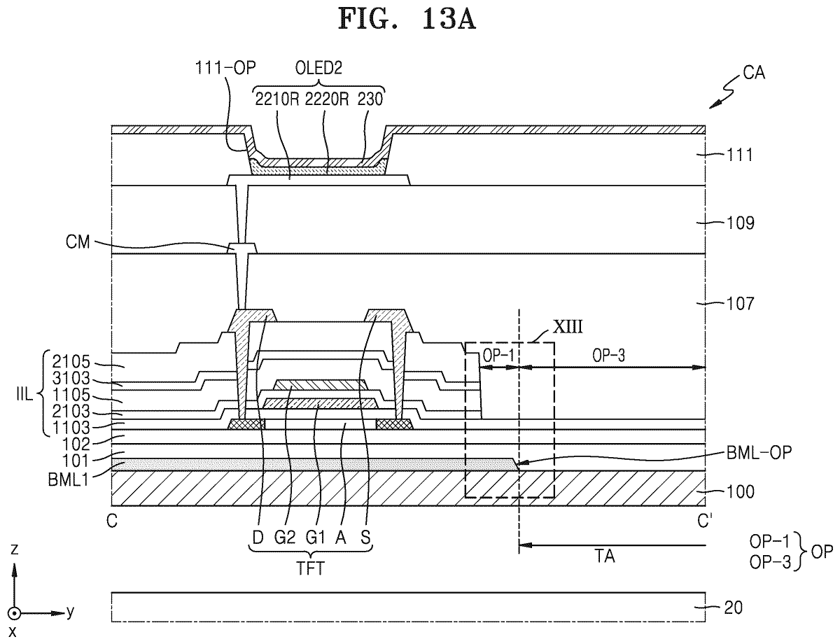

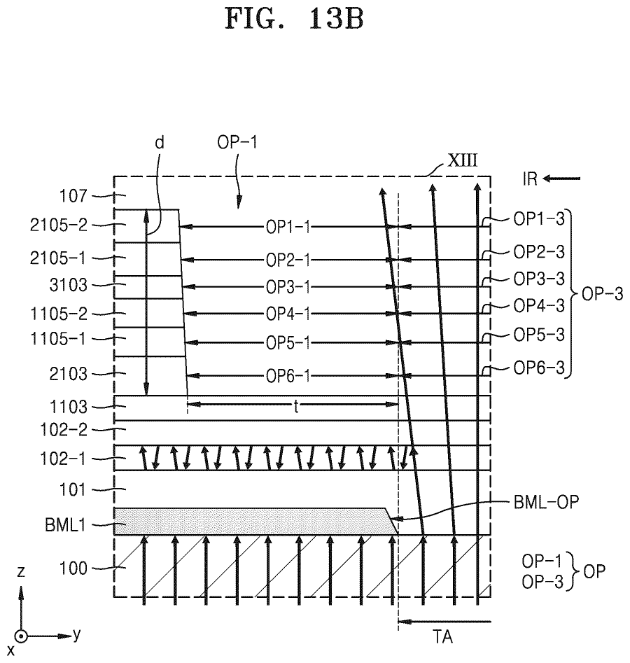

FIG. 13A is a cross-sectional view schematically illustrating a portion of an electronic device including a display panel, according to another embodiment. FIG. 13A may be a cross-sectional view of the display panel taken along line C-C′ in one of several examples of the embodiment shown in FIG. 12.

Referring to FIG. 13A, the opening OP may overlap the transmissive area TA. For example, the opening OP may include a first opening OP-1 overlapping the first bottom metal layer BML1 and a third opening OP-3 overlapping the transmissive area TA. In other words, the opening OP may extend in the +y direction from one side of the inorganic insulation layer IIL in which the first opening OP-1 is formed.

The bottom metal layer may include an opening BML-OP arranged between the first bottom metal layer BML1 and the second bottom metal layer BML2 (FIG. 12), and the transmissive area TA and the third opening OP-3 may overlap the opening BML-OP of the bottom metal layer.

FIG. 13B is an enlarged cross-sectional view schematically illustrating a portion of an electronic device including a display panel according to another embodiment. FIG. 13B may be an enlarged cross-sectional view illustrating area XIII of FIG. 13A.

Referring to FIG. 13B, an opening OP may be formed penetrating the second-2 interlayer insulation layer 2105-2, the second-1 interlayer insulation layer 2105-1, the third gate insulation layer 3103, the first-2 interlayer insulation layer 1105-2, the first-1 interlayer insulation layer 1105-1, and the second gate insulation layer 2103. The first and third openings OP-1 and OP-3 may include portions corresponding to each of these layers.

A first portion OP1-1 of the first opening OP-1 penetrates the second-2 interlayer insulation layer 2105-2 and may overlap the first bottom metal layer BML1. A first portion OP1-3 of the third opening OP-3 penetrates the second-2 interlayer insulation layer 2105-2 and may overlap the transmissive area TA.

A second portion OP2-1 of the first opening OP-1 penetrates the second-1 interlayer insulation layer 2105-1 and may overlap the first bottom metal layer BML1. A second portion OP2-3 of the third opening OP-3 penetrates the second-1 interlayer insulation layer 2105-1 and may overlap the transmissive area TA.

A third portion OP3-1 of the first opening OP-1 penetrates the third gate insulation layer 3103 and may overlap the first bottom metal layer BML1. A third portion OP3-3 of the third opening OP-3 penetrates the third gate insulation layer 3103 and may overlap the transmissive area TA.

A fourth portion OP4-1 of the first opening OP-1 penetrates the first-2 interlayer insulation layer 1105-2 and may overlap the first bottom metal layer BML1. A fourth portion OP4-3 of the third opening OP-3 penetrates the first-2 interlayer insulation layer 1105-2 and may overlap the transmissive area TA.

A fifth portion OP5-1 of the first opening OP-1 penetrates the first-1 interlayer insulation layer 1105-1 and may overlap the first bottom metal layer BML1. A fifth portion OP5-3 of the third opening OP-3 penetrates the first-1 interlayer insulation layer 1105-1 and may overlap the transmissive area TA.

A sixth portion OP6-1 of the first opening OP-1 penetrates the second gate insulation layer 2103 and may overlap the first bottom metal layer BML1. A sixth portion OP6-3 of the third opening OP-3 penetrates the second gate insulation layer 2103 and may overlap the transmissive area TA.

The horizontal distance from an edge of the first bottom metal layer BML1 to one side of the opening OP may be greater than the depth of the opening OP. In some embodiments, the horizontal distance t from the edge of the first bottom metal layer BML1 to one side of the first opening OP-1 may be greater than the depth d of the opening OP. For example, the horizontal distance t may be about 4 micrometers (μm), and the depth d may be about 1 micrometer (μm) to about 2 micrometers (μm).

The first opening OP-1 and third opening OP-3 may be at least partially filled with the first organic insulation layer 107.

When comparing the embodiment shown in FIG. 13B to the embodiment shown in FIG. 6B, the addition of the third opening OP-3 may remove layers (for example, the second-1 interlayer insulation layer 2105-1, the first-1 interlayer insulation layer 1105-1, and the second gate insulation layer 2103) along which light may proceed, e.g., in the −y direction, due to total internal reflection within the transmissive area TA, such that total internal reflection through those layers does not occur in the embodiment of FIG. 13B because those layers on not present in the transmissive area TA. In some embodiments, this may be an effect of the removal of layers including silicon nitride (SiNₓ) (for example, second gate insulation layer 2103 and first-1 interlayer insulation layer 1105-1). Thus, the embodiment illustrated in FIG. 13B may be more effective at preventing light transmission to the thin-film transistor compared to the embodiment illustrated in FIG. 6B.

The embodiment of FIG. 13B may allow light may to proceed along the first buffer layer 102-1 due to the cross-talk between the first buffer layer 102-1 and the second buffer layer 102-2.

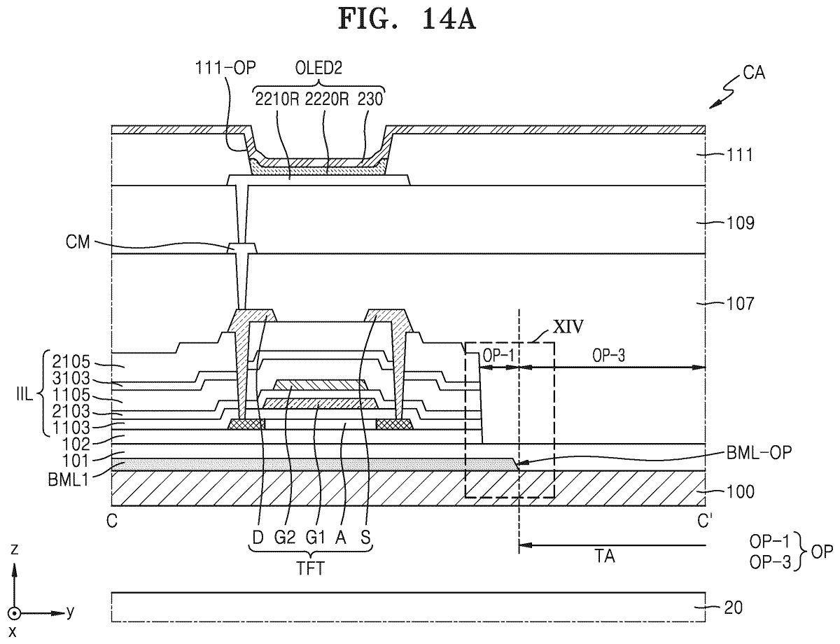

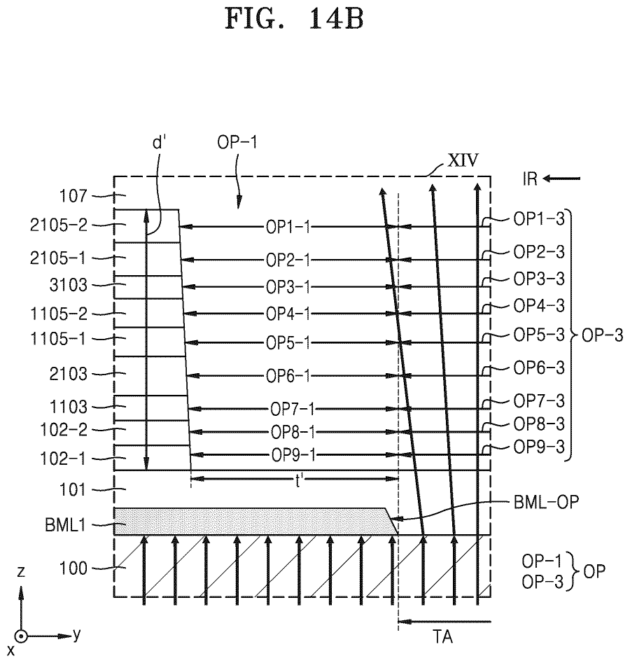

FIG. 14A is a cross-sectional view schematically illustrating a portion of an electronic device including a display panel, according to another embodiment. FIG. 14A may be a cross-sectional view of the display panel taken along line C-C′ in one of several examples of the embodiment shown in FIG. 12.

Referring to FIG. 14A, a portion of the first gate insulation layer 1103 and the buffer layer 102 may be additionally removed from the embodiment shown in FIG. 13A. Thus, an opening OP may be formed through the buffer layer 102, the first to third gate insulation layers 1103, 2103, and 3103, and the first and second interlayer insulation layers 1105 and 2105. In this case, the opening OP may expose a portion of the upper surface of the barrier layer 101.

The opening OP may be at least partially filled by the first organic insulation layer 107. Thus, a portion of the upper surface of the barrier layer 101 may be covered by the first organic insulation layer 107.

FIG. 14B is an enlarged cross-sectional view schematically illustrating a portion of an electronic device including a display panel according to another embodiment. FIG. 14B may be an enlarged cross-sectional view illustrating area XIV of FIG. 14A.

Referring to FIG. 14B, an opening OP may be formed penetrating the second-2 interlayer insulation layer 2105-2, the second-1 interlayer insulation layer 2105-1, the third gate insulation layer 3103, the first-2 interlayer insulation layer 1105-2, the first-1 interlayer insulation layer 1105-1, the second gate insulation layer 2103, the first gate insulation layer 1103, the second buffer layer 102-2, and the first buffer layer 102-1.

The first and third openings OP-1 and OP-3 may include portions respectively corresponding to these layers.

A first portion OP1-1 of the first opening OP-1 penetrates the second-2 interlayer insulation layer 2105-2 and may overlap the first bottom metal layer BML1. A first portion OP1-3 of the third opening OP-3 penetrates the second-2 interlayer insulation layer 2105-2 and may overlap the transmissive area TA.

A second portion OP2-1 of the first opening OP-1 penetrates the second-1 interlayer insulation layer 2105-1 and may overlap the first bottom metal layer BML1. A second portion OP2-3 of the third opening OP-3 penetrates the second-1 interlayer insulation layer 2105-1 and may overlap the transmissive area TA.

A third portion OP3-1 of the first opening OP-1 penetrates the third gate insulation layer 3103 and may overlap the first bottom metal layer BML1. A third portion OP3-3 of the third opening OP-3 penetrates the third gate insulation layer 3103 and may overlap the transmissive area TA.

A fourth portion OP4-1 of the first opening OP-1 penetrates the first-2 interlayer insulation layer 1105-2 and may overlap the first bottom metal layer BML1. A fourth portion OP4-3 of the third opening OP-3 penetrates the first-2 interlayer insulation layer 1105-2 and may overlap the transmissive area TA.

A fifth portion OP5-1 of the first opening OP-1 penetrates the first-1 interlayer insulation layer 1105-1 and may overlap the first bottom metal layer BML1. A fifth portion OP5-3 of the third opening OP-3 penetrates the first-1 interlayer insulation layer 1105-1 and may overlap the transmissive area TA.

A sixth portion OP6-1 of the first opening OP-1 penetrates the second gate insulation layer 2103 and may overlap the first bottom metal layer BML1. A sixth portion OP6-3 of the third opening OP-3 penetrates the second gate insulation layer 2103 and may overlap the transmissive area TA.

A seventh portion OP7-1 of the first opening OP-1 penetrates the first gate insulation layer 1103 and may overlap the first bottom metal layer BML1. A seventh portion OP7-3 of the third opening OP-3 penetrates the first gate insulation layer 1103 and may overlap the transmissive area TA.

An eighth portion OP8-1 of the first opening OP-1 penetrates the second buffer layer 102-2 and may overlap the first bottom metal layer BML1. An eighth portion OP8-3 of the third opening OP-3 penetrates the second buffer layer 102-2 and may overlap the transmissive area TA.

A ninth portion OP9-1 of the first opening OP-1 penetrates the first buffer layer 102-1 and may overlap the first bottom metal layer BML1. A ninth portion OP9-3 of the third opening OP-3 penetrates the first buffer layer 102-1 and may overlap the transmissive area TA.

The horizontal distance from an edge of the first bottom metal layer BML1 to one side of the opening OP may be greater than the depth of the opening OP. In some embodiments, unlike shown in FIG. 14B, a horizontal distance t′ from an edge of the first bottom metal layer BML1 to one side of the first opening OP-1 may be greater than a depth d′ of the opening OP. For example, the horizontal distance t′ may be about 4 micrometers (μm), and the depth d′ may be about 1 micrometer (μm) to about 2 micrometers (μm).

The first opening OP-1 and third opening OP-3 may be at least partially filled with the first organic insulation layer 107.

When comparing the embodiment shown in FIG. 14B to the embodiment shown in FIG. 7B, the addition of the third opening OP-3 may remove layers (for example, the second-1 interlayer insulation layer 2105-1, the first-1 interlayer insulation layer 1105-1, the second gate insulation layer 2103, and the first buffer layer 102-1) through which light may proceed due to total internal reflection within an area overlapping the transmissive area TA, so that total internal reflection in those layers does not occur. In some embodiments, this may be an effect of the removal of layers including silicon nitride (SiNₓ) (for example, second gate insulation layer 2103, first-1 interlayer insulation layer 1105-1, and first buffer layer 102-1). Thus, the embodiment illustrated in FIG. 14B may be more effective at preventing light transmission to the thin-film transistor compared to the embodiment illustrated in FIG. 7B.

In some embodiments, the amount of light transmitted to the thin-film transistor when the embodiment illustrated in FIG. 7B is applied to an electronic device may be about 9 times to about 10 times the amount of light transmitted to the thin-film transistor when the embodiment illustrated in FIG. 14B is applied to an electronic device. In other words, the light blocking effect of the embodiment illustrated in FIG. 14B may be about 9 times to about 10 times the light blocking effect of the embodiment illustrated in FIG. 7B.

While FIG. 14B illustrates that a portion of the barrier layer 101 has not been removed in the area overlapping the opening OP, the disclosure is not limited thereto. In another embodiment, the barrier layer 101 may also be removed in the area overlapping the first and third openings OP-1 and OP-3. In this case, a portion of the upper surface of the first bottom metal layer BML1 may be exposed and may be covered by the first organic insulation layer 107.

The disclosure has been described with reference to embodiments illustrated in the drawings, which are only for example, and one of ordinary knowledge in the art will understand that various modifications and other equally valid embodiments are possible therefrom. Therefore, the scope of the disclosure and the claims below is not limited to the specific embodiments illustrated or described.

According to an embodiment made as described above, a display panel may block or prevent both direct light and diffracted light from being incident on the thin-film transistor. Of course, these effects do not limit the scope of the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate comprising a transmissive area;
a transistor disposed over the substrate to be adjacent to the transmissive area;
a light-emitting diode electrically connected to the transistor;
a bottom metal layer disposed between the substrate and the transistor and overlapping the transistor; and
a plurality of inorganic insulation layers disposed between the bottom metal layer and the light-emitting diode,
wherein an opening penetrating at least one of the inorganic insulation layers overlaps the bottom metal layer.

2. The display panel of claim 1,
further comprising an organic insulation layer that at least partially fills the opening in the plurality of inorganic insulation layers.

3. The display panel of claim 1, further comprising:
a shielding layer comprising a metallic material, the shielding layer at least partially filling the opening in the plurality of inorganic insulation layers.

4. The display panel of claim 3,
wherein the shielding layer is in contact with the bottom metal layer.

5. The display panel of claim 1,
wherein the opening has a closed-loop shape when viewed in a plan view.

6. The display panel of claim 1,
wherein the bottom metal layer comprises an opening corresponding to the transmissive area, and
the opening in the plurality of inorganic insulation layers overlaps the opening in the bottom metal layer.

7. The display panel of claim 1,
wherein the plurality of inorganic insulation layers includes a plurality of layers that have different refractive indices.

8. The display panel of claim 1,
wherein the bottom metal layer comprises an opening corresponding to the transmissive area,
the opening in the plurality of inorganic insulation layers comprises a first inner surface adjacent to the transistor, and
a horizontal distance from an edge of the bottom metal layer defining the opening in the bottom metal layer to the first inner surface is greater than a depth of the opening in the plurality of inorganic insulation layers.

9. The display panel of claim 8,
wherein the opening in the plurality of inorganic insulation layers further comprises a second inner surface opposite the first inner surface and adjacent to the transmissive area, and
a horizontal distance from the edge of the bottom metal layer to the second inner surface is greater than a depth of the opening of the plurality of inorganic insulation layers.

10. An electronic device, comprising:
a display panel comprising a display area; and
a component disposed on a rear surface of the display panel and overlapping the display area,
wherein the display panel comprises,
a substrate comprising a transmissive area overlapping the component;
a transistor disposed over the substrate to be adjacent to the transmissive area;
a light-emitting diode electrically connected to the transistor;
a bottom metal layer disposed between the substrate and the transistor and overlapping the transistor; and
a plurality of inorganic insulation layers disposed between the bottom metal layer and the light-emitting diode,
wherein an opening penetrating at least one of the inorganic insulation layers overlaps the bottom metal layer.

11. The electronic device of claim 10,
wherein the component comprises a sensor or camera.

12. The electronic device of claim 10,
further comprising an organic insulation layer that at least partially fills the opening in the plurality of inorganic insulation layers.

13. The electronic device of claim 10,
further comprising a shielding layer comprising a metallic material, the shielding layer at least partially filling the opening in the plurality of inorganic insulation layers.

14. The electronic device of claim 13,
wherein the shielding layer is in contact with the bottom metal layer.

15. The electronic device of claim 10,
wherein the opening has a closed-loop shape when viewed in a plan view.

16. The electronic device of claim 10,
wherein the bottom metal layer comprises an opening corresponding to the transmissive area, and the opening in the plurality of inorganic insulation layers overlaps the opening in the bottom metal layer.

17. The electronic device of claim 10,
wherein the plurality of inorganic insulation layers comprises a plurality of layers that have different refractive indices.

18. The electronic device of claim 10,
wherein the bottom metal layer comprises an opening corresponding to the transmissive area,
the opening in the plurality of inorganic insulation layers comprises a first inner surface adjacent to the transistor, and
a horizontal distance from an edge of the bottom metal layer defining the opening in the bottom metal layer to the first inner surface is greater than a depth of the opening in the plurality of inorganic insulation layers.

19. The electronic device of claim 18,
wherein the opening of the plurality of inorganic insulation layers further comprises a second inner surface opposite the first inner surface and adjacent to the transmissive area, and
a horizontal distance from the edge of the bottom metal layer to the second inner surface is greater than a depth of the opening of the plurality of inorganic insulation layers.

20. The electronic device of claim 10,
wherein the opening reduces an amount of light reaching the transistor out of light emitted from the component.
